(19) United States
(12) Patent Application Publication
(10) Pub. No.: US 2023/0343597 A1
(43) Pub. Date: Oct. 26, 2023

(54) STRUCTURE MANUFACTURING METHOD AND STRUCTURE MANUFACTURING APPARATUS

(71) Applicant: SUMITOMO CHEMICAL COMPANY, LIMITED, Tokyo (JP)

(72) Inventors: Fumimasa HORIKIRI, Hitachi-shi (JP); Noboru FUKUHARA, Hitachi-shi (JP)

(73) Assignee: SUMITOMO CHEMICAL COMPANY, LIMITED, Tokyo (JP)

(21) Appl. No.: 17/799,406

(22) PCT Filed: Feb. 12, 2021
(86) PCT No.: PCT/JP2021/005225

§ 371 Date: Aug. 12, 2022

(30) Foreign Application Priority Data
Feb. 13, 2020 (JP) 2020-022443

(51) Int. Cl. H01L 21/306; H01L 21/67

(52) U.S. Cl. CPC H01L 21/30612; H01L 21/6708

(57) ABSTRACT

There is provided a structure manufacturing method, including: preparing an etching target at least whose top surface comprises group III nitride crystal, and an alkaline or acidic etching liquid containing peroxodisulfate ion as an oxidizing agent that receives electrons; irradiating the top surface of the etching target with light while rotating the etching target, with the top surface of the etching target immersed in the etching liquid heated to generate sulfate ion radicals.

### TECHNICAL FIELD

The present disclosure relates to a structure manufacturing method and a structure manufacturing apparatus.

### DESCRIPTION OF RELATED ART

Group III nitrides such as gallium nitride (GaN) are used as materials for manufacturing semiconductor devices such as light emitting devices and transistors. Further, group III nitrides are also attracting attention as materials for microelectromechanical systems (MEMS).

Photoelectrochemical (PEC) etching has been proposed as an etching technique for forming various structures on group III nitrides such as GaN (see, for example, Non-Patent document 1). PEC etching is a wet etching with less damage than general dry etching, and the PEC etching is preferable in the point that an apparatus is simpler than special dry etching with less damage such as neutral particle beam etching (see, for example, Non-Patent Document 2) and atomic layer etching (see, for example, Non-Patent Document 3).

### PRIOR ART DOCUMENT

### Non-Patent Document

[Non-patent document 1] J. Murata et al., “Photo-electrochemical etching of free-standing GaN wafer surfaces grown by hydride vapor phase epitaxy”, Electrochimica Acta 171 (2015) 89-95
[Non-Patent Document 2] S. Samukawa, JJAP, 45(2006)2395.
[Non-Patent Document 3] T. Faraz, ECS J. Solid Stat. Scie. & Technol., 4, N5023 (2015).

### SUMMARY OF THE DISCLOSURE

### Problem to be Solved by the Disclosure

An object of the present disclosure is to provide a novel technique that can be used for PEC etching for a group III nitride.

Another object of the present disclosure is to provide a technique capable of improving a controllability of etching conditions such as an etching rate in the PEC etching for the group III nitride.

### Means for Solving the Problem

According to an aspect of the present disclosure, there is provided a structure manufacturing method, including:
preparing an etching target at least whose top surface comprises group III nitride crystal, and an alkaline or acidic etching liquid containing peroxodisulfate ion as an oxidizing agent that receives electrons; irradiating the top surface of the etching target with light while rotating the etching target, with the top surface of the etching target immersed in the etching liquid heated to generate sulfate ion radicals.

According to other aspect of the present disclosure, there is provided a structure manufacturing apparatus, including:
a holding unit that rotatably holds an etching target at least whose top surface comprises group III nitride crystal;
a supply unit that supplies an alkaline or acidic etching liquid containing peroxodisulfate ions as an oxidizing agent that receives electrons, onto the top surface of the etching target;
a heater that heats the etching liquid;
a light irradiation device that irradiates the top surface of the etching target with light;
a control device that controls the holding unit, the supply unit, the heater, and the light irradiation device to irradiate the top surface of the etching target with light while rotating the etching target, with the top surface of the etching target immersed in the etching liquid heated to generate sulfate ion radicals.

### Advantage of the Disclosure

There is provided a novel technique that can be used for PEC etching for group III nitrides.

### BRIEF DESCRIPTION OF THE DRAWINGS

FIG. 1 is a schematic cross-sectional view illustrating a structure manufacturing apparatus (treatment apparatus) according to a first embodiment of the present disclosure.

FIG. 2 (a) to 2 (c) are schematic cross-sectional views illustrating a PEC etching step according to a first embodiment.

FIGS. 3 (a) and 3 (b) are schematic cross-sectional views illustrating a post-treatment step according to a first embodiment.

FIG. 4 (a) is a schematic cross-sectional view illustrating an object to be treated according to a first example, and FIG. 4 (b) is a schematic cross-sectional view illustrating an etching step for performing PEC etching to the object to be treated according to a first example.

FIG. 5 (a) is a schematic cross-sectional view illustrating an object to be treated according to a second example, and FIG. 5 (b) is a schematic cross-sectional view illustrating an etching step of performing PEC etching to the object to be treated according to a second example.

FIGS. 6 (a) and 6 (b) are schematic cross-sectional views illustrating a stirring device according to a first modified example and a second modified example of the first embodiment, respectively.

FIG. 7 is a schematic cross-sectional view illustrating a fixing device according to a modified example of the first embodiment.

FIG. 8 is a graph showing a wavelength dependence of a transmittance of a potassium persulfate aqueous solution.

FIG. 9 is a graph showing a pH change when a mixed solution of the potassium hydroxide aqueous solution and the peroxodisulfate potassium aqueous solution is heated.

FIG. 10 is a graph showing a pH change when the mixed solution of a potassium hydroxide aqueous solution and the peroxodisulfate potassium aqueous solution is heated.

FIG. 11 is a table summarizing the results obtained from an experiment of FIG. 10.

FIG. 12 is a graph showing changes in temperature and pH of an etching liquid over time in the experimental example of the first embodiment.

FIG. 13 is a graph showing a relationship between an etching temperature and an etching rate in the experimental example of the first embodiment.

FIG. 14 (a) is a schematic cross-sectional view illustrating a group III nitride semiconductor device according to a second embodiment, and FIG. 14 (b) is a schematic cross-sectional view illustrating a laminated substrate which is a material of the group III nitride semiconductor device according to a second embodiment.

FIG. 15 (a) is a schematic plan view illustrating a group III nitride semiconductor device shown as an embodiment of a wafer, and FIG. 15 (b) is a schematic plan view illustrating a group III nitride semiconductor device shown as an embodiment of a chip.

FIG. 16 is a schematic cross-sectional view illustrating a PEC etching apparatus according to a second embodiment.

FIGS. 17 (a), 17 (b), and 17 (c) are schematic plan views of the vicinity of an etching target of the PEC etching apparatus according to the second embodiment, the PEC etching apparatus according to a first modified example of the second embodiment, and the PEC etching apparatus according to a second modified example of the second embodiment, respectively FIGS. 18 (a) and 18 (b) are partial schematic cross-sectional views of an etching target and illustrating an outline of a PEC etching step according to a second embodiment.

FIGS. 19 (a) and 19 (b) are optical micrographs showing a laminated substrate after PEC etching according to an experimental example of the second embodiment.

FIGS. 20 (a) and 20 (b) are AFM images of the laminated substrate according to an experimental example of the second embodiment.

FIG. 21 is a schematic view illustrating the vicinity of a light source of the etching apparatus according to another aspect of the second embodiment in which another light source is additionally provided in the light irradiation device.

FIG. 22 is a schematic view illustrating the vicinity of the etching target of the PEC etching apparatus according to a third embodiment.

FIG. 23 (a) is a schematic view illustrating the vicinity of the etching target of the PEC etching apparatus according to a modified example of the third embodiment, and FIG. 23 (b) to 23 (d) are distributions of schematic irradiation intensity.

### DETAILED DESCRIPTION OF THE DISCLOSURE

### First Embodiment

A technique for manufacturing a structure according to a first embodiment of the present disclosure will be described. In the present embodiment, there is provided a technique (thermal PEC etching) that applies heating to an etching liquid in photoelectrochemical (PEC) etching for group III nitride.

First, a mechanism of PEC etching for the group III nitride according to the present embodiment will be described. Here, an example of a group III nitride that is PEC-etched is gallium nitride (GaN). Hereinafter, the PEC etching for the group III nitride is also simply referred to as etching.

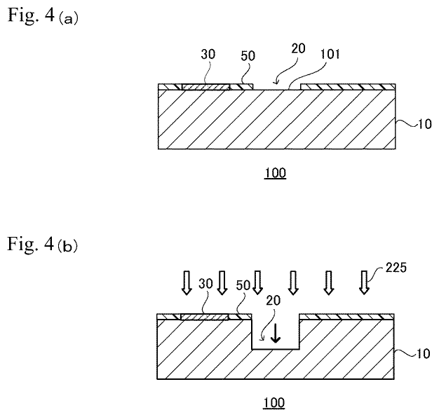

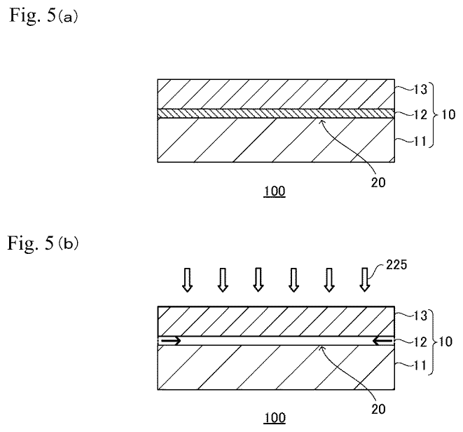

An object to be PEC-etched is referred to as an object to be treated. The object to be treated has at least an etching target, and the etching target has a region to be etched, which comprises a group III nitride. Details of the object to be treated will be described later with reference to FIG. 4 (a) to 5 (b).

PEC etching is wet etching, and is performed, with the object to be treated immersed in an etching liquid. The etching liquid used here is an alkaline or acidic etching liquid containing oxygen used to form an oxide of a group III element contained in the group III nitride that constitutes a region to be etched, and further containing an oxidizing agent that receives electrons.

Peroxodisulfate ion (S₂O₈²⁻) is preferably used as the oxidizing agent, and an aqueous solution in which a salt of (at least) peroxodisulfate ion (S₂O₈²⁻) is dissolved in water at a predetermined concentration is used as the etching liquid. More specifically, the oxidizing agent functions in such a manner that a sulfate ion radical (SO₄⁻*) generated from S₂O₈²⁻ receives an electron and changes into a sulfate ion (SO₄²⁻). Hereinafter, the sulfate ion radical may be referred to as an SO₄^{-*} radical.

The reaction in PEC etching of the present embodiment can be summarized as in (Chemical formula 1).

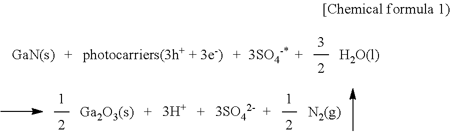

As shown in (Chemical formula 1), by irradiating the group III nitride with light having a wavelength or less corresponding to a band gap of the group III nitride (in this example, light having a wavelength of 365 nm or less corresponding to the band gap of GaN), holes (h⁺) and electrons (e⁻) are generated in the group III nitride. Due to the generation of the holes, the group III nitride (GaN in this example) is decomposed into group III element cations (Ga³⁺ in this example) and nitrogen gas (N₂ gas), and due to the combination of the cations of the group III element and the oxygen contained in water (H₂O), an oxide of the group III element (Ga₂O₃ in this example) is generated. Then, due to dissolution of the oxide of the group III element in the alkaline or acidic etching liquid, the group III nitride is etched. Then, due to combination with SO₄^{-*} to generate SO₄², the electrons generated in the group III nitride are consumed. As the PEC etching progresses, a hydrogen ion (H+) concentration increases, which causes pH of the etching liquid to decrease.

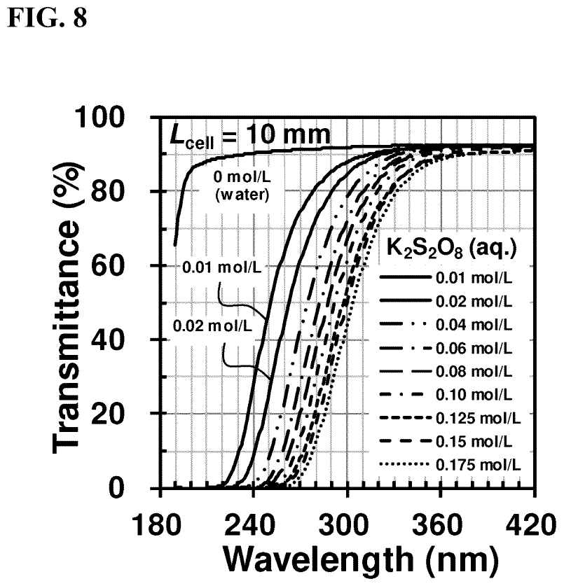

Since S₂O₈²⁻ contained in the etching liquid is consumed as the etching progresses, the S₂O₈²⁻ concentration in the etching liquid changes (decreases) over time. In order to clarify a regulation of S₂O₈²⁻ concentration, the concentration at the time of preparation, which is the S₂O₈²⁻ concentration at the time when the etching liquid is prepared (that is, a charging concentration and an initial concentration of S₂O₈²⁻ determined by a recipe for preparing the etching liquid), is defined as a standard S₂O₈²⁻ concentration of the etching liquid. Hereinafter, the concentration at the time of preparation of S₂O₈²⁻ in the etching liquid (and an aqueous solution or a mixed solution used in an experiment described with reference to FIGS. 8 to 11) may be simply referred to as a S₂O₈²⁻ concentration.

Although S₂O₈²⁻ eventually changes to SO₄²⁻ interposing SO₄⁻*, the concentration of the combined components of S₂O₈²⁻ S₄^{-*} and SO₄²⁻ converted to S₂O₈²⁻ or the concentration converted to SO₄²⁻ is constant over time.

The reaction for producing SO₄^{-*} from S₂O₈²⁻ contained in the etching liquid is shown by (Chemical formula 2). That is, SO₄^{-*} can be generated by at least one of heating S₂O₈²⁻ and irradiating S₂O₈²⁻ with light. Hereinafter, the generation of SO₄^{-*} by heating may be referred to as thermal radical generation, and the generation of SO₄^{-*} by light irradiation may be referred to as photoradical generation.

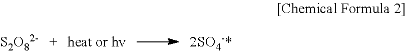

Here, “heating” means that the temperature of an object to be heated is at least 30° C., which is higher than room temperature (25±5° C., 20° C. or higher and 30° C. or lower), including not only raising a temperature 30° C. or lower of the object to a temperature above 30° C., but also maintaining the temperature above 30° C. of the object to a temperature above 30° C.

In the PEC etching according to the present embodiment, due to consuming the electrons generated together with the holes by irradiating the group III nitride with light, by S₂O₈²⁻ which is contained as an oxidizing agent in the etching liquid (more specifically, by SO₄^{-*} generated from S₂O₈²⁻), PEC etching can progress. That is, PEC etching can be performed in such a manner that electrons are directly emitted from the object to be treated into the etching liquid (without going through external wiring).

In contrast, a PEC etching technique without using such an oxidizing agent includes PEC etching in such manner that the electrons generated in the group III nitride are discharged into the etching liquid from a cathode electrode immersed in the etching liquid, through wiring extending outside the etching liquid. In contrast to PEC etching with electrodes using such a cathode electrode, PEC etching according to the present embodiment is an electrodeless (contactless) PEC etching that does not require such a cathode electrode.

In the present embodiment, PEC etching using thermal radical generation is proposed as a method for producing SO^{4-*}, as will be described in more detail in an experimental example described later. Thereby, it becomes easy to efficiently improve various forms of PEC etching, for example, an etching rate, which could not be achieved by PEC etching using photoradical generation (only), and further, for example, it becomes easy to selectively etch a predetermined region to be etched. PEC etching using thermal radical generation is also referred to as thermal PEC etching.

PEC etching can also be performed to a group III nitride other than the exemplified GaN. The group III element contained in the group III nitride may be at least one of aluminum (Al), gallium (Ga) and indium (In). The concept of PEC etching for an Al component or an In component in the group III nitride is the same as the concept described with reference to (Chemical formula 1) for the Ga component. That is, by generating holes by irradiating the group III nitride with light, an oxide of Al or an oxide of In is generated, and by dissolving these oxides in an alkaline or acidic etching liquid, PEC etching can be performed. A wavelength of the irradiation light (for example, a peak wavelength) may be appropriately changed depending on a composition of the group III nitride to be etched. When Al is contained based on the PEC etching of GaN, light having a shorter wavelength may be used, and when In is contained, light having a longer wavelength can also be used. That is, depending on the composition of the group III nitride to be etched, light having a wavelength to allow the group III nitride to be PEC-etched, can be appropriately selected and used. If necessary, impurities such as conductivity type determining impurities may be added to the group III nitride to be PEC-etched.

The generation of photoradicals will be further described. FIG. 8 is a graph showing a wavelength dependence of a transmittance of an aqueous solution of potassium persulfate (K₂S₂O₈). FIG. 8 shows a transmittance when the S₂O₈²⁻ concentration is changed from 0.01 mol/L to 0.175 mol/L, and also shows a transmittance of water. A transmission length of a sample cell used in this experiment is 10 mm, that is, a thickness of an aqueous solution through which light is transmitted, is 10 mm.

Although the wavelength dependence of the transmittance changes to some extent depending on the S₂O₈²⁻ concentration, it is understood from FIG. 8 that S₂O₈²⁻ largely absorbs light of less than 310 nm as a general tendency. In the photoradical generation, SO₄^{-*} is generated from S₂O₈²⁻ by such light absorption. When the wavelength is less than 200 nm, the light absorption by water becomes large. Accordingly, the photoradical generation progresses efficiently by irradiation with light having a wavelength of 200 nm or more and less than 310 nm.

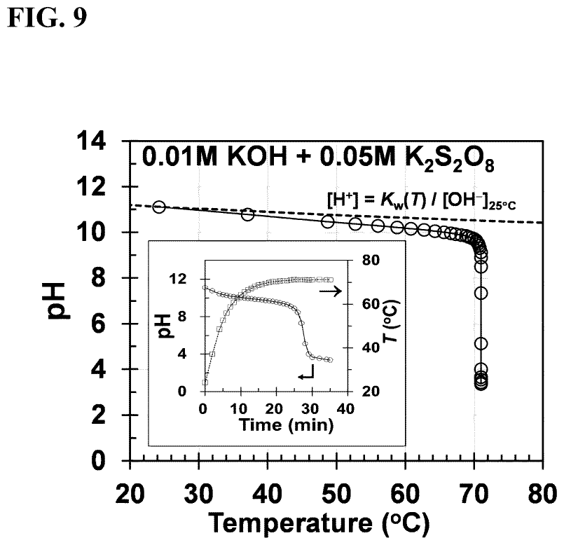

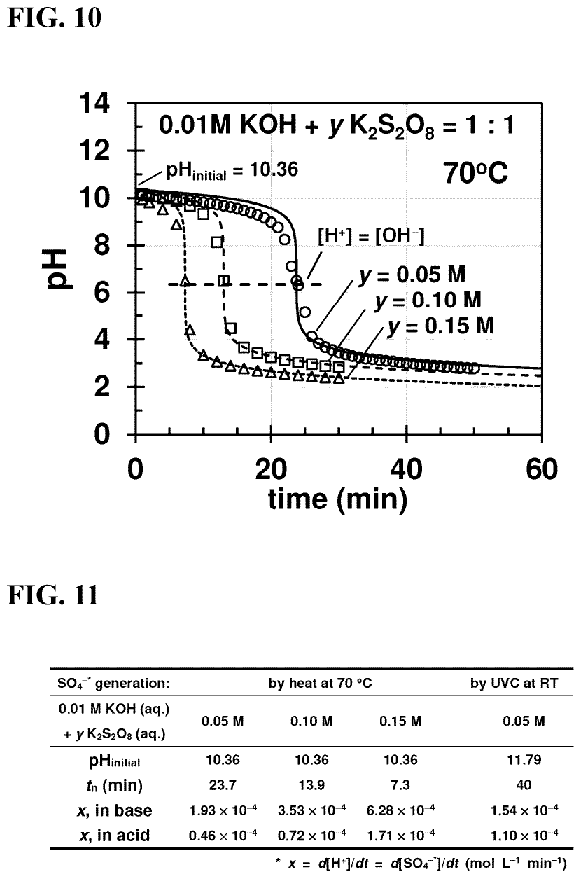

Thermal radical generation will be further described. FIGS. 9 and 10 are graphs showing a pH change when a mixed solution of an aqueous solution of potassium hydroxide (KOH) and an aqueous solution of potassium persulfate (K₂S₂O₈) is heated. A single K₂S₂O₈ aqueous solution is acidic, but by mixing the K₂S₂O₈ aqueous solution with the KOH aqueous solution, the pH of the mixed solution can be alkaline.

In the experiment according to FIG. 9, a mixed solution of a 0.01 mol/L (M) KOH aqueous solution and a 0.05 mol/L (M) K₂S₂O₈ aqueous solution at a ratio of 1:1 (that is, a mixed solution having an S₂O₈²⁻ concentration of 0.025 mol/L) was heated to 70° C. The graph shown in an inner region of FIG. 9 is a graph showing a time change of a temperature of the mixed solution and a time change of the pH of the mixed solution. The graph represented by a white circle shown in FIG. 9 is a graph in which the graph shown in the inner region of FIG. 9 is re-plotted into one graph as a relationship between the temperature and pH of the mixed solution. The graph shown by a broken line shown in FIG. 9 is a graph showing a pH change due to only the temperature change of an ionic product of water of the aqueous solution having the same pH as that of the mixed solution at a temperature of 20° C., as a reference.

As shown in the graph of the inner region of FIG. 9, about 25 to 30 minutes after the temperature has risen to approximately 70° C., the pH drops sharply from alkaline to acidic. This reveals that by heating the mixed solution to 70° C., SO₄^{-*} is generated from S₂O₈², and SO₄²⁻ is further generated from SO₄⁻*.

As shown in the graph of the broken line in FIG. 9, the pH also decreases due to the change of the ionic product of water as a result of increase of the temperature. As shown in the graph of the white circle in FIG. 9, the pH of the mixed solution is dissociated downward from the graph of the broken line, and this dissociation indicates that the pH is lowered due to the generation of thermal radicals. The pH decrease due to the generation of thermal radicals is observed from around 35° C., and tends to increase as the temperature increases. Further, it can be understood that this tendency becomes remarkable at around 70° C.

In the experiment according to FIG. 10, each of a mixed solution of a 0.01 mol/L (M) KOH aqueous solution and a 0.05 mol/L (M) K₂S₂O₈ aqueous solution mixed at 1:1 (that is, a mixed solution having an S₂O₈²⁻ concentration of 0.025 mol/L), a mixed solution of a 0.01 mol/L (M) KOH aqueous solution and a 0.10 mol/L (M) K₂S₂O₈ aqueous solution mixed at 1:1 (that is, a mixed solution having an S₂O₈²⁻ concentration of 0.05 mol/L), and a mixed solution of a 0.01 mol/L (M) KOH aqueous solution and a 0.15 mol/L (M) K₂S₂O₈ aqueous solution mixed at 1:1 (that is, a mixed solution having an S₂O₈²⁻ concentration of 0.075 mol/L), was heated to 70° C. In this experiment, in order to reduce an error until the temperature rises to 70° C., each mixed solution was prepared by dissolving a predetermined amount of K₂S₂O₈ powder in a KOH aqueous solution preheated to 70° C.

In these mixed solutions, the higher the S₂O₈²⁻ concentration, the earlier the pH decreases from alkaline to acidic. This reveals that the higher the S₂O₈²⁻ concentration, the higher (faster) the SO₄²⁻ (that is, SO₄^{-*}) is generated.

More specifically, a reaction for producing SO₄²⁻ from SO₄^{-*} can be shown by (Chemical formula 3) in an alkaline aqueous solution and by (Chemical formula 4) in an acidic aqueous solution. Based on (Chemical formula 3) and (Chemical formula 4), a SO₄^{-*} generation rate can be calculated by calculating a time change rate of the pH of the etching liquid (that is, a hydrogen ion generation rate) for each of the alkaline region and the acidic region.

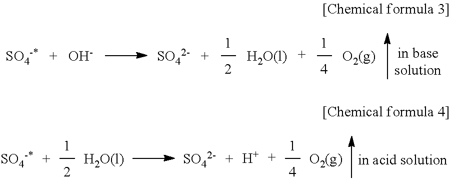

FIG. 11 is a table summarizing the results obtained from the experiment according to FIG. 10. In the column of “by heat at 70° C.”, the results of thermal radical generation obtained from the experiment according to FIG. 10 are shown. “y” indicates the concentration of the K₂S₂O₈ aqueous solution used for preparing each mixed solution related to thermal radical generation. FIG. 11 also shows the results of photoradical generation in the column of “by UVC at RT”.

The results of the photoradical generation are the results obtained from the experiment according to FIG. 10 and another experiment, and are the results measured for a mixed solution of 0.01 M KOH aqueous solution and 0.05 M K₂S₂O₈ aqueous solution mixed at 1:1 at room temperature (that is, a mixed solution having an S₂O₈²⁻ concentration of 0.025 mol/L).

In FIG. 11, “pHᵢₙₜₑᵣₙₐₗ” is the pH at an initial time. Here, the initial time is the time when the K₂S₂O₈ powder is dissolved in the KOH aqueous solution at 70° C., and “tₙ (min)” indicates the time in minutes from the initial time to the time of neutralization, and “X in base” and “x in acid” indicate a hydrogen ion generation rate (d [H+]/dt) in (mol/L)/minute units, in the alkaline region and the acidic region, respectively. Here, as understood from (Chemical formula 1), the hydrogen ion generation rate is considered to be equal to the SO₄²⁻ generation rate, and the SO₄²⁻ generation rate is considered to be equal to the SO₄^{-*} generation rate (which has a short life), and therefore it can be said that the hydrogen ion generation rate is equal to the SO₄^{-*} generation rate. The SO₄^{-*} generation rate may be hereinafter referred to as a radical generation rate.

In the result of thermal radical generation (at 70° C., i.e. above 45° C.), the radical generation rates of the alkaline region and the acidic region are higher as the S₂O₈ concentration is higher. The radical generation rate achieved by photoradical generation (at room temperature, i.e. below 45° C.) (the higher radical generation rate achieved by photoradical generation in the alkaline region. this is also referred to as a radical generation rate by light hereinafter) is 1.54×10⁻⁴ (mol/L)/min.

In the generation of thermal radicals in the alkaline region, any one of the S₂O₈²⁻ radical generation rate 1.93×10⁻⁴ (mol/L)/min with a concentration of 0.025 mol/L (y=0.05 M), S₂O₈²⁻ radical generation rate −3.53×10⁻⁴ (mol/L)/min with a concentration of 0.05 mol/L (y=0.10 M), and S₂O₈²⁻ radical generation rate 6.28×10⁻⁴ (mol/L)/min with a concentration of 0.075 mol/L (y=0.15 M) has a high radical generation rate of 1.6×10⁻⁴ (mol/L)/min or more, which exceeds the radical generation rate of 1.54×10⁻⁴ (mol/L)/min by light.

Further, in the generation of thermal radicals in the acidic region, S₂O₈²⁻ radical generation rate 1.71×10⁻⁴ (mol/L)/min with a concentration of 0.075 mol/L (y=0.15 M), is a high radical generation rate of 1.6×10⁻⁴ (mol/L)/min or more, which exceeds the radical generation rate of 1.54×10⁻⁴ (mol/L)/min by light.

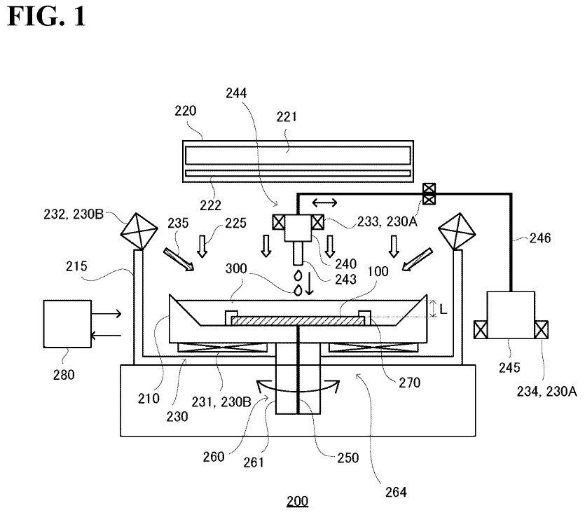

Next, a structure manufacturing apparatus according to a first embodiment will be described. FIG. 1 is a schematic cross-sectional view illustrating a structure manufacturing apparatus (a treatment apparatus for an object to be treated 100) 200 (hereinafter, also referred to as a treatment apparatus 200) according to a first embodiment.

The treatment apparatus 200 includes: an inner container 210, an outer container 215, a light irradiation device 220, a heater 230, a supply unit 244 (an injection device 240, etc.), a thermometer 250, a holding unit 264 (a stirring device 260, a rotating device 261, etc.), a fixing device 270, and a control device 280.

The inner container 210 houses the object to be treated 100 and the treatment liquid 300 such as the etching liquid 310. The inner container 210 is also simply referred to as a container 210 below. The outer container 215 houses the container 210. The light irradiation device 220 irradiates the object to be treated 100 with light 225. The heater 230 heats the etching liquid 310. The injection device 240 injects the treatment liquid 300 such as the etching liquid 310 into the container 210. The thermometer 250 measures the temperature of the etching liquid 310. The stirring device 260 stirs the etching liquid 310 contained in the container 210. The fixing device 270 fixes the object to be treated 100 contained in the container 210 to the container 210. The control device 280 controls the light irradiation device 220, the heater 230, the supply unit 244, the holding unit 264, etc., so as to perform a predetermined operation. The control device 280 is configured by using, for example, a personal computer.

The treatment liquid 300 is a treatment liquid that is injected into the container 210 and used for various types of treatment applied to the object to be treated 100. The treatment liquid used for the various forms of treatment is referred to as a treatment liquid 300 when there is no particular distinction as to in what kind of treatment the liquid is used. The treatment liquid 300 is, for example, an etching liquid 310 used for a PEC etching treatment performed in the etching step described later, and for example, the post-treatment liquid 320 used for a post-treatment performed in the post-treatment step described later.

The container 210 is rotatably held by a rotating device 261 provided so as to also serve as a stirring device 260. The rotating device 261 rotates the container 210 at a predetermined timing and in a predetermined direction and speed.

The holding unit 264 has the container 210 and the rotating device 261 and rotatably holds (houses) the object to be treated 100 (etching target 10) and the treatment liquid 300. The container 210 houses the object to be treated 100 (etching target 10) and the treatment liquid 300, and by rotating the container 210 by the rotating device 261, the treatment liquid 300 can be rotated together with the object to be treated 100 (etching target 10).

The light irradiation device 220 has a light source 221, and the light source 221 emits light 225 containing at least a wavelength component that generates a hole in the group III nitride constituting the region to be etched 20 of the object to be treated 100. The light 225 may or may not have a wavelength component (that is, a wavelength component that causes photoradical generation) of (200 nm or more) and less than 310 nm, if necessary. The light irradiator 220 (or the light source 221) may have a filter 222 that attenuates (or transmits) the wavelength component in a predetermined range, if necessary. The light irradiation device 220 irradiates a top surface 101 (of the etching target 10) of the object to be treated 100 with light 225.

The heater 230 is a heater in various modes of heating the etching liquid 310. When the heaters provided in various modes are not particularly distinguished as to what kind of heater they are, it is called a heater 230. The heater 230 is, for example, a pre-injection heater 230A that heats the etching liquid 310 before being injected (contained) in the container 210, and is, for example, a post-injection heater 230B that heats the etching liquid 310 after being injected (contained) in the container 210.

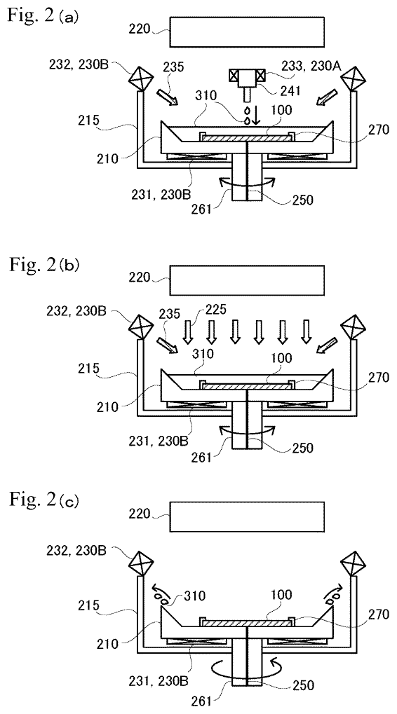

The treatment apparatus 200 exemplified in the present embodiment has an injection device heater 233 as the pre-injection heater 230A. The injection device heater 233 is provided in an etching liquid injection device 241 (see FIG. 2 (a)), to heat the etching liquid 310 so that the heated etching liquid 310 is injected into the container 210 from the etching liquid injection device 241.

The treatment apparatus 200 exemplified in the present embodiment has a container heater 231 and a lamp heater 232 as the post-injection heater 230B. The container heater 231 is provided in the container 210, and by heating the container 210, the etching liquid 310 in the container 210 is heated. The lamp heater 232 is provided, for example, in the outer container 215, and by irradiating the etching liquid 310 in the container 210 with infrared rays 235, the etching liquid 310 is heated. If necessary, one of the container heater 231 and the lamp heater 232 may be omitted.

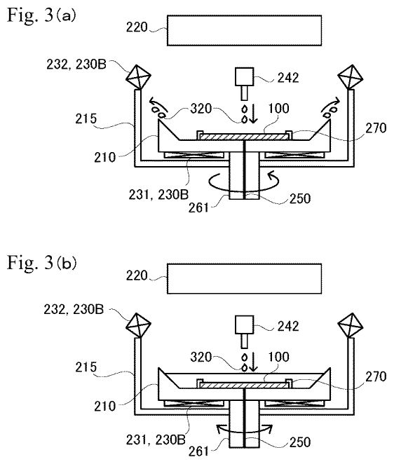

The injection device (discharging device) 240 is an injection device in various modes of injecting (discharging) the treatment liquid 300 into the container 210. When the injection devices provided in various modes are not particularly distinguished as to what kind of injection device they are, it is called an injection device 240. The injection device 240 is, for example, an etching liquid injection device 241 (see FIG. 2 (a)) that injects the etching liquid 310 into the container 210 as the treatment liquid 300, and is, for example, a post-treatment liquid injection device 242 (see FIG. 3 (a)) that injects the post-treatment liquid 320 into the container 210 as the treatment liquid 300.

If necessary, the treatment apparatus 200 may have a moving device for moving a discharge portion (tip portion) 243 of the injection device 240 for injecting the treatment liquid 300. The moving device, for example, moves the discharge portion 243 upward the inside of the container 210 when injecting the treatment liquid 300, and moves (retracts) the discharge portion 243 after injecting the treatment liquid 300, upward the outside of the container 210 (to a position that does not hinder the light irradiation to the region to be treated 20).

The treatment apparatus 200 may have a tank 245 that houses the treatment liquid 300 supplied to the discharge portion 243 of the injection device 240. The treatment liquid 300 is supplied from the tank 245 to the discharge portion 243 of the injection device 240 through a pipe 246.

The supply unit 244 has various members and mechanisms for supplying the treatment liquid 300 (for example, etching liquid 310, and for example, post-treatment liquid 320) contained in the tank 245 onto the top surface 101 of the object to be treated 100. In this example, the supply unit 244 has the pipe 246 and the injection device 240.

In the present embodiment, supplying the treatment liquid 300 onto the top surface 101 also includes flowing the treatment liquid 300 injected onto the region outside the top surface 101 in a plan view onto the top surface 101, and is not limited to injecting the treatment liquid 300 onto the region included in the top surface 101 in a plan view.

An injection device spare heater 234 may be provided as the pre-injection heater 230A in the tank 245, etc., for the etching liquid 310. The injection device heater 233 is arranged on a downstream side (discharging unit 243 side) of the injection device spare heater 234, and for example, the etching liquid 310 heated by the injection device spare heater 234 is heated to further higher temperature.

As the thermometer 250, various types of thermometers may be used, for example, a thermocouple may be used. The thermometer 250 is preferably arranged at a position where a shadow of the thermometer 250 due to the light 225 is not reflected on the region to be etched 20 (that is, at a position that does not hinder the irradiation to the region to be etched 20 with light). Specifically, the thermometer 250 with the thermocouple is arranged at a bottom of the container 210, for example. The thermometer 250 may directly measure the temperature of the etching liquid 310, or may indirectly measure the temperature of the etching liquid 310 by measuring the temperature of the object to be treated 100, the container 210, etc.

It is preferable that the inner surface portion of the container 210 in contact with (at least) the etching liquid 310 and the object to be treated 100 are heated to the same temperature as the etching liquid 310 when heating the etching liquid 310, to maintain a temperature uniformity of the etching liquid 310 contained in the container 210.

A stirring device 260 is a stirring device in various modes of stirring the etching liquid 310 contained in the container 210. When the stirring devices provided in various modes are not particularly distinguished as to what kind of stirring devices they are, it is called a stirring device 260. The stirring device 260 is for stirring the etching liquid 310 by moving the container 210, for example, or is for stirring the etching liquid 310 by moving a stirring member in the etching liquid 310.

The treatment apparatus 200 exemplified in the present embodiment has a rotating device 261 as the stirring device 260 in a mode of stirring the etching liquid 310 by moving the container 210. Specifically, by driving the rotating device 261 so that a rotation direction is reversed at predetermined intervals, or by driving the rotating device 261 so as to intermittently repeat the rotation in one direction, the rotating device 261 is used as the stirring device 260.

As the fixing device 270, various types of fixing devices may be used, and for example, the fixing device in a mode of suppressing a movement of the object to be treated 100 in a radial direction and a thickness direction (upward direction) by arranging a plurality of hook-shaped fixing members discretely in a circumferential direction of the object to be processed 100 on an outer peripheral portion of the object to be treated 100, may be used.

Next, a structure manufacturing method according to a first embodiment will be described, and the treatment apparatus 200 will be further described. The structure manufacturing method according to the present embodiment includes at least an etching step in which PEC etching is used, and preferably further includes a post-treatment step performed after the etching step.

First, the etching step will be described. In order to perform the etching step, the object to be treated 100 (etching target 10) and the etching liquid 310 are prepared. FIG. 2 (a) to FIG. 2 (c) are schematic cross-sectional views illustrating the etching step of the present embodiment. In the etching step of the present embodiment, first, as in the step illustrated in FIG. 2 (a), the object to be treated 100 is contained in the container 210 in a state of being immersed in the etching liquid 310. More specifically, by injecting the etching liquid 310 from the etching liquid injection device 241 into the container 210 containing the object to be treated 100, the object to be treated 100 is immersed in the etching liquid 310.

In the present embodiment, since the top surface 101 of the object to be treated 100 (etching target 10) is contained in the container 210 so that the top surface 101 of the object to be treated 100 (etching target 10) is submerged in the etching liquid 310, an entire top surface 101 of the object to be treated 100 (etching target 10) can be immersed in the etching liquid 310. When the top surface 101 of the etching target 10 is submerged in the etching liquid 310, a liquid level of the etching liquid 310 in contact with an inner side surface of the container 210 is placed at a position higher than the top surface 101.

When the mask 50, etc., is formed on the top surface 101, the fact that the entire top surface 101 is immersed in the etching liquid 310 means that an entire area (a region to be etched 20) of the top surface 101 that is not covered by the mask 50, etc., and is exposed, is immersed so as to be in contact with the etching liquid 310, or means that each region of the top surface 101 is immersed in the etching liquid 310 so as to be in contact with the etching liquid 310 or through a mask 50, etc.

A distance L (see FIG. 1, hereinafter referred to as a placement depth L) from the surface of the etching liquid 310 to the top surface of the object to be treated 100 may be, for example, 1 mm or more and 100 mm or less (for example, about 10 mm). When the placement depth L is excessively small, there is a concern that the top surface of the object to be treated 100 may not be maintained in a state of being immersed in the etching liquid 310 due to evaporation of the etching liquid 310, movement of the etching liquid 310 due to stirring, and the like. Therefore, the placement depth L is preferably, for example, 1 mm or more, and more preferably 5 mm or more. Further, when the placement depth L is excessively large, an amount of the etching liquid 310 contained in the container 210 becomes unnecessarily large, so that the etching liquid 310 cannot be used efficiently. Therefore, the placement depth L is preferably 100 mm or less, for example.

Next, as in the step illustrated in FIG. 2 (b), the region to be etched 20 is etched by heating the etching liquid 310 to a predetermined temperature, to generate SO₄^{-*} in the etching liquid 310, and by irradiating the region to be etched 20 of the object to be treated 100 with light 225 to generate holes in the group III nitride constituting the region to be etched 20. The predetermined temperature (the temperature of the etching liquid 310 at the time of etching, that is, the etching temperature) is 45° C. or higher (for example, 70° C.). The temperature of the etching liquid 310 is also hereinafter referred to as a liquid temperature. Details of preferable conditions in the thermal PEC etching will be described in experimental examples described later.

By irradiating the region to be etched 20 with light while keeping the liquid temperature at 45° C. or higher, PEC etching according to the present embodiment is started. Examples of a method for setting the liquid temperature at the time of etching to 45° C. or higher include, for example, a method of a first example described below. In the method of the first example, the etching liquid 310 having a temperature of 45° C. or higher set by the pre-injection heater 230A such as the injection device heater 233, is injected into the container 210 (see FIG. 2 (a)). After injecting into the container 210, in order to maintain the liquid temperature at the time of etching (during light irradiation) at 45° C. or higher, heating may be performed by a post-injection heater 230B such as a container heater 231, etc. When the liquid temperature may decrease (while maintaining 45° C. or higher) during etching (light irradiation), heating by the post-injection heater 230B may not be performed.

In the method of the first example, the etching liquid 310 preheated to a temperature lower than 45° C. and somewhat high (for example, 35° C. or higher, for example, 40° C. or higher) by the injection device spare heater 234, may be further heated to 45° C. or higher (to the etching temperature) by the injection device heater 233 and injected into the container 210. By preheating the etching liquid 310 by the injection device spare heater 234, the etching liquid 310 being the solution before being heated by the injection device heater 233, the liquid temperature can be rapidly raised to 45° C. or higher by the injection device heater 233.

Examples of a method for setting the liquid temperature at the time of etching to 45° C. or higher include a method of a second example described below. In the method of the second example, first, the etching liquid 310, which has been preheated to a temperature lower than 45° C. and somewhat high (for example, 35° C. or higher, for example, 40° C. or higher) by the pre-injection heater 230A such as the heater 233, is injected into the container 210 (see FIG. 2 (a)). Then, the liquid temperature is raised to 45° C. or higher (to the etching temperature) and kept at 45° C. or higher by the post-injection heater 230B such as the container heater 231. By preliminarily heating the etching liquid 310 at the time of injecting into the container 210, the liquid temperature can be quickly raised to 45° C. or higher after injection.

Even when the liquid temperature is 45° C. or higher, PEC etching does not progress unless there is no irradiation with light 225, and therefore SO₄^{-*} is wasted. Therefore, from a viewpoint of performing PEC etching by efficiently using SO₄⁻*, it is preferable to start irradiation with light 225 immediately after setting the liquid temperature to 45° C. or higher.

From such a viewpoint, it is preferable that the injection device heater 233 is provided in the vicinity of the discharging unit 243 of the etching liquid injection device 241. Thereby, it is possible to prevent a time interval from when the etching liquid 310 is heated by the injection device heater 233 until it is used for etching (in the method of the first example) to be unnecessarily long. It is preferable that the injection device heater 233 is provided to a member (a member in the vicinity of the discharging unit 243) moved by the moving device, for example, in a mode in which the discharging unit 243 of the etching liquid injection device 241 is movably held by the moving device. It is also preferable that the injection device heater 233 is provided, for example, to the pipe 246 connecting the tank 245 for the etching liquid 310 and the discharging unit 243 of the etching liquid injection device 241.

In this example, in order to make an explanation easier to understand, an embodiment in which etching is performed by injecting the etching liquid 310 into the container 210 in the step shown in FIG. 2 (a) and then starting irradiation with light 225 in the step shown in FIG. 2(b), has been described. However, if necessary, PEC etching may be performed by injecting the etching liquid 310 into the container 210, that is, by emitting the light 225 while supplying (flowing) the etching liquid 310 onto the top surface 101 of the etching target 10 (see also FIG. 1). In this case, it is preferable that the light irradiation device 220, the holding unit 264 (container 210), and the member are arranged at a position where a shadow of the member due to the light 225, the member constituting the treatment apparatus 200 (for example, the member constituting a discharge port for the etching liquid 310 in the supply unit 244), is not reflected on the top surface 101 (on the region to be etched 20). For example, the etching liquid 310 may be injected (discharged) onto the region outside the top surface 101 in a plan view. By performing PEC etching while supplying a new etching liquid 310, it becomes easy to perform PEC etching while keeping the quality of the etching liquid 310 constant, that is, to suppress deterioration of the etching liquid 310. The etching liquid 310 overflowing from the container 210 may be discharged into the outer container 215.

The heater 230 is preferably controlled based on a liquid temperature measured by the thermometer 250. Thereby, the temperature of the etching liquid 310 at the time of etching can be stably controlled.

Further, at the time of etching, that is, when the etching liquid is heated, the etching liquid 310 contained in the container 210 is preferably stirred by the rotating device 261. Thereby, it is possible to improve the uniformity of the temperature of the etching liquid 310 at the time of etching (it is possible to suppress temperature unevenness depending on a position). Stirring may be performed from the time of injecting the etching liquid 310 into the container 210. When the rotating device 261 is used for stirring without supplying the new etching liquid 310, the rotating device 261 may be driven so that the container 210 rotates with such a force that the etching liquid 310 does not overflow from the container 210 during stirring.

In the present embodiment, by rotating the container 210 (the holding unit 264), the etching liquid 310 is rotated together with the object to be treated 100 (the etching target 10). Thereby, the etching liquid 310 easily rotates while following the etching target 10, and PEC etching can be performed, with a relative movement of the etching liquid 310 with respect to the top surface (surface to be etched) 101, that is, with respect to the region to be etched 20, suppressed as compared with, for example, that of the second embodiment, or the direction of the movement differentiated from that of the second embodiment described later. Since the PEC etching for the group III nitride is often unknown, it is preferable that various etching methods having different modes of movement of the etching liquid 310 with respect to the region to be etched 20 can be appropriately selected and used because the degree of technical freedom can be improved.

According to the present embodiment, PEC etching is performed in such manner that the top surface 101 of the etching target 10 is irradiated with light 225 while rotating the object to be treated 100 (etching target 10), with the top surface 101 of the etching target 10 immersed in the etching liquid 310 heated so as to generate sulfate ion radicals. By irradiating the top surface 101 with light 225 while rotating the etching target 10, the distribution of irradiation intensity (power density) on the top surface 101 can be uniform in a circumferential direction of rotation, and in-plane uniformity of PEC etching conditions can be improved.

As can be understood from (Chemical formula 1), etc., in PEC etching, bubbles due to gas such as N₂ gas are generated. In the thermal PEC etching according to the present embodiment, as will be described in an experimental example described later, a high etching rate is obtained, and due to such a high etching rate, the generation of bubbles becomes remarkable. Therefore, movement of the object to be treated 100 due to the generation of bubbles is likely to occur, and temporal fluctuations in etching conditions due to such movement are likely to become a problem. Temporal fluctuations in etching conditions due to such movement of the object to be treated 100 have not been a problem in conventional PEC etching in which only photoradical generation is used.

Therefore, in the present embodiment, it is preferable to perform PEC etching in a state where the object to be treated 100 is fixed to the container 210 by the fixing device 270. Thereby, since it is possible to suppress the movement of the object to be treated 100 due to the generation of bubbles as described above, PEC etching can progress under a stable condition.

Next, as in the step shown in FIG. 2 (c), the etching liquid 310 is discharged from the container 210. In the treatment apparatus 200 of the present embodiment, the etching liquid 310 is discharged from the container 210 by rotating the container 210 by the rotating device 261 to scatter the etching liquid 310 toward the outer periphery. The scattered etching liquid 310 is collected in the outer container 215. As described above, the etching step according to the present embodiment is performed.

A series of steps shown in FIGS. 2 (a) and 2 (c) may be performed once or may be repeated a plurality of times as needed. For example, the series of steps may be performed a plurality of times (that is, a plurality of times while replacing the etching liquid 310) in order to perform etching for a long time to form a deep recess.

Next, a post-treatment step will be described. FIGS. 3 (a) and 3 (b) are schematic cross-sectional views illustrating the post-treatment step of the present embodiment. FIGS. 3 (a) and 3 (b) show the post-treatment steps of a first example and a second example, respectively.

The post-treatment step is a treatment step performed after the etching step, and is a step performed by injecting the post-treatment liquid 320 into the container 210 containing the object to be treated 100. The post-treatment step is, for example, a washing step. In the washing step, the object to be treated 100 is washed using, for example, water as the post-treatment liquid (washing liquid) 320.

The post-treatment step is also, for example, a flattening etching step. The group III nitride crystal constituting the region to be etched 20 contains a dislocation, and since a lifetime of the hole is short in the dislocation, PEC etching is unlikely to occur. Therefore, convex portions are likely to be formed at a position corresponding to the dislocation as undissolved portions during PEC etching. In a flattening etching step, etching is performed to remove the convex portion (lower the convex portion). As the post-treatment liquid (flattening etching liquid) 320 when performing flattening etching, for example, hydrochloric acid (HCl) aqueous solution, a mixed aqueous solution of hydrochloric acid (HCl) and hydrogen peroxide (H₂O₂) (hydrochloric acid hydrogen peroxide), a mixed aqueous solution of sulfuric acid (H₂SO₄) and hydrogen peroxide (H₂O₂) (piranha solution), tetramethylammonium hydroxide (TMAH) aqueous solution, hydrogen fluoride aqueous solution (fluoric acid), potassium hydroxide (KOH) aqueous solution, etc., are used. In the flattening etching step, more specifically, for example, etching treatment is performed for 10 minutes using hydrochloric acid hydrogen peroxide in which 30% HCl and 30% H₂O₂ are mixed at a ratio of 1:1. After the flattening etching step, a cleaning step may be performed as a further post-treatment step. In the flattening etching step, it is not necessary to emit the light 225 from the light irradiation device 220.

In the post-treatment step of the first example shown in FIG. 3 (a), the post-treatment step is performed in such a manner that the post-treatment liquid 320 is injected into the container 210 from the post-treatment liquid injection device 242, and the container 210 is rotated by the rotating device 261 to discharge the post-treatment liquid 320. More specifically, the post-treatment liquid 320 is supplied to the center on the top surface of the object to be treated 100, and is moved by centrifugal force so as to spread on the top surface of the object to be treated 100 toward the outer periphery, and is further discharged to the outer peripheral side of the container 210.

In the post-treatment step of the second example shown in FIG. 3 (b), the post-treatment step is performed in such a manner that by injecting the post-treatment liquid 320 from the post-treatment liquid injection device 242 into the container 210 to a level higher than the top surface of the object to be treated 100, the object to be treated 100 is immersed (submerged) in the post-treatment liquid 320. During the post-treatment step, the post-treatment liquid 320 may be stirred by driving the rotating device 261 to such an extent that the post-treatment liquid 320 is not completely discharged from the container 210. When the post-treatment is completed, the post-treatment liquid 320 is discharged from the container 210 by scattering the post-treatment liquid 320 to the outer peripheral side in the same manner as the discharge of the etching liquid 310 described with reference to FIG. 2 (c).

In the post-treatment step of the present embodiment, it is preferable to perform post-treatment to the object to be treated 100 with an unheated (that is, a temperature of 30° C. or lower) post-treatment liquid. Thereby, the object to be treated 100 heated in the etching step (for example, to 70° C.) can be quickly cooled (preferably to 30° C. or lower), and a work of taking out the object to be treated 100 from the container 210 can be facilitated. That is, the post-treatment step preferably also serves as a cooling step for cooling the object to be treated 100. Therefore, the post-treatment liquid injection device 242 preferably injects the unheated post-treatment liquid 320 into the container 210. The post-treatment liquid may be actively cooled to less than 20° C. (less than room temperature) before use. As described above, the post-treatment step according to the present embodiment is performed.

Next, the object to be treated 100 will be further described. The object to be treated 100 has at least etching target 10. At least the top surface (surface to be etched) 101 of the etching target 10 comprises group III nitride crystal, and there is the region to be etched 20 in at least a part of the top surface 101.

FIG. 4 (a) is a schematic cross-sectional view illustrating the object to be treated 100 of a first example. The object to be treated 100 of the first example has an etching target (wafer) 10 and a mask 50. The etching target 10 has the region to be etched 20 comprising the group III nitride, on (at least) the top surface portion of the etching target 10. The mask 50 is formed on the top surface of the etching target 10 and has an opening defining the region to be etched 20. The mask 50 comprises, for example, a conductive material such as a metal, and also comprises a non-conductive material such as silicon nitride (SiNₓ), silicon oxide (SiO₂), or a resist.

The etching target 10 is, for example, a member having conductivity in a total thickness. Examples of such an etching target 10 include a free-standing substrate of group III nitride such as a GaN substrate, and further, for example, a laminated substrate in which a group III nitride layer such as a GaN layer is epitaxially grown on such a free-standing substrate.

The etching target 10 is, for example, a member whose top surface side is conductive and whose bottom surface side (back surface side) is semi-insulating (hereinafter, also referred to as a non-conductive member on the back surface side). Examples of such an etching target 10 include a laminated substrate in which a group III nitride layer such as a GaN layer is epitaxially grown on a substrate such as a sapphire substrate or a semi-insulating silicon carbide (SiC) substrate.

When the back surface side of the etching target 10 comprises a non-conductive member and the mask 50 comprises a non-conductive material, it is preferable that the object to be treated 100 further has a cathode pad (conductive member) 30.

The cathode pad 30 is a conductive member comprising a conductive material such as metal, and is provided so as to be in contact with at least a part of a surface of a conductive region of the etching target 10 which is electrically connected to the region to be etched 20. The cathode pad 30 is provided so that at least a part of the cathode pad 30, for example, the top surface thereof is in contact with the etching liquid 310 during PEC etching.

The region to be etched 20 where PEC etching occurs is considered to function as an anode region where holes are consumed. In contrast, it is considered that the surface of the cathode pad 30 which is a conductive member electrically connected to the region to be etched 20, in contact with the etching liquid 310 functions as a cathode region where electrons are consumed (released). When the back surface side of the etching target 10 comprises a non-conductive member and the mask 50 comprises a non-conductive material, it becomes difficult to secure a cathode region in which electrons are consumed, unless the cathode pad 30 is formed. Even in such a case, by forming the cathode pad 30, it becomes easy to secure the cathode region, so that PEC etching can be promoted.

When the etching target 10 comprises a member having conductivity in a total thickness, the bottom surface (back surface) or the side surface of the etching target 10, preferably a bottom surface having a large area, can be used as the cathode region, even when the mask 50 comprises a non-conductive material. Therefore, the cathode pad 30 may be omitted. When using the bottom surface of the etching target 10 as the cathode region, it is preferable that the object to be treated 100 is placed so that the bottom surface of the etching target 10 is in contact with the etching liquid 310. Details of such an embodiment will be described later with reference to FIG. 7.

Further, even when the etching target 10 comprises a member having conductivity in a total thickness or the back surface of the etching target 10 comprises a non-conductive member, the top surface of the mask 50 can be used as the cathode region as long as the mask 50 comprises a conductive material. Therefore, the cathode pad 30 may be omitted.

FIG. 4 (b) is a schematic cross-sectional view illustrating the etching step of performing PEC etching to the object to be treated 100 according to a first example. The region to be etched 20 is etched by irradiating the region to be etched 20 with light 225 in the etching liquid 310. In this example, as shown by a thick arrow of a solid line, the etching progresses in a thickness direction from a top surface side to a bottom surface side of the etching target 10.

It is known that it is difficult to etch the +c plane (for example, Ga plane of GaN) of group III nitride. However, the group III nitride can be etched by PEC etching regardless of a crystal orientation, and therefore even in a case of the +c plane, it can be etched. Accordingly, when the surface to be etched (top surface) of the region to be etched 20 is the +c plane, it is particularly useful to perform etching using PEC etching. Since the PEC etching is a wet etching, it also has an advantage that a damage to the group III nitride crystal due to the etching is small.

FIG. 5 (a) is a schematic cross-sectional view illustrating the object to be treated 100 of a second example. The object to be treated 100 of the second example comprises only the etching target (wafer) 10, and do not have to have the mask 50. The etching target 10 has a lower layer 11, an intermediate layer 12 arranged on the lower layer 11, and an upper layer 13 arranged on the intermediate layer 12.

The intermediate layer 12 comprises group III nitride, and an entire intermediate layer 12 constitutes the region to be etched 20. The upper layer 13 comprises the group III nitride that transmits light 225 by having a band gap wider than that of the group III nitride constituting the intermediate layer 12. More specifically, for example, the lower layer 11 is a growth base substrate such as a sapphire substrate and a SiC substrate, and the intermediate layer 12 is an indium gallium nitride (InGaN) layer grown on the lower layer 11 (base substrate for growth), and the upper layer 13 is a GaN layer grown on the intermediate layer 12 (InGaN layer). Hereinafter, explanation will be given by taking such a laminated structure as an example. In this example, a top surface of the upper layer 13 can be used as a cathode region. If necessary, another layer may be interposed between the lower layer 11 and the intermediate layer 12, or another layer (transmitting light 225) may be interposed between the intermediate layer 12 and the upper layer 13. The base substrate for growth may be a conductive substrate such as a silicon (Si) substrate, and in such a case, the bottom surface of the lower layer 11 can also be used as a cathode region.

FIG. 5 (b) is a schematic cross-sectional view illustrating an etching step of performing PEC etching to the object to be treated 100 according to a second example. By transmitting light 225 through the upper layer 13 and irradiating the intermediate layer 12 being the region to be etched 20 with light 225, the intermediate layer 12 is selectively etched with respect to the upper layer 13. In this example, a wavelength of the light 225 is more than 365 nm so that it can transmit through the upper layer 13 comprising GaN, and in the intermediate layer 12 comprising InGaN, the wavelength is set in a range such that it is absorbed, generating holes.

In the PEC etching of this example, etching is performed with an end face of the intermediate layer 12 in contact with the etching liquid 310. In this way, as shown by a thick arrow of a solid line, the etching of the intermediate layer 12 progresses in a direction orthogonal to a thickness direction (in-plane direction) from an end face side to an inner side of the etching target 10. The lower layer 11 and the upper layer 13 are separated by removing an entire intermediate layer 12 by etching. In this way, in this example, PEC etching can be used to perform lift-off that separates the upper layer 13 from the lower layer 11.

When lift-off, that is, selective etching of the intermediate layer 12 with respect to the upper layer 13 is performed by PEC etching, it is preferable to use thermal PEC etching. Attempting to perform lift-off PEC etching by PEC etching utilizing photoradical generation causes the following difficulties. In order to generate photoradicals, the etching liquid 310 is irradiated with light having a wavelength of less than 310 nm. However, when the light 225 contains a component having a wavelength of 310 nm or less, light absorption (hole generation) occurs not only in the intermediate layer 12 (InGaN layer) but also in the upper layer 13 (GaN layer), and therefore the upper layer 13 is also etched. Accordingly, when the photoradical generation is used, selective etching of the intermediate layer 12 cannot be performed.

In this way, when applying PEC etching, for example, to lift-off, it is preferable to emit the light 225 from the light irradiation device 220, which is the light that causes generation of holes in the group III nitride that constitutes the region to be etched 20 (whose wavelength corresponding to the band gap is at least 310 nm or more) and suppresses photoradical generation in the etching liquid 310. That is, the light irradiation device 220 is preferably configured to emit light 225 in which a short wavelength component having a wavelength of less than 310 nm is cut (attenuated).

Such a light irradiation device 220 may be configured as follows. For example, a semiconductor light emitting element comprising a semiconductor material having a wavelength corresponding to a band gap of 310 nm or more is used as the light source 221 of the light irradiation device 220. Thereby, light having a short wavelength component of a wavelength of less than 310 nm is suppressed from being emitted from the light source 221.

Further for example, the light irradiation device 220 includes a filter 222 that attenuates a short wavelength component having a wavelength of less than 310 nm. Thereby, even when the light source 221 having a wide range of emission wavelengths such as a high-pressure halogen lamp is used, it is possible to suppress that the light 225 emitted from the light irradiation device 220 has a short wavelength component of a wavelength of less than 310 nm.

The short wavelength component cut (attenuated) in the light 225 is not limited to the short wavelength component having a wavelength of less than 310 nm, and is not limited to the short-wave component having a predetermined wavelength (a predetermined wavelength included in a range of the wavelength of 310 nm or more) or less, if necessary. For example, in the lift-off example described above, light 225 in which the short wavelength component having a wavelength of 365 nm or less is cut, is used. That is, here, it can be said that the light 225 is a light in which the short wavelength component having a wavelength of at least 310 nm is cut.

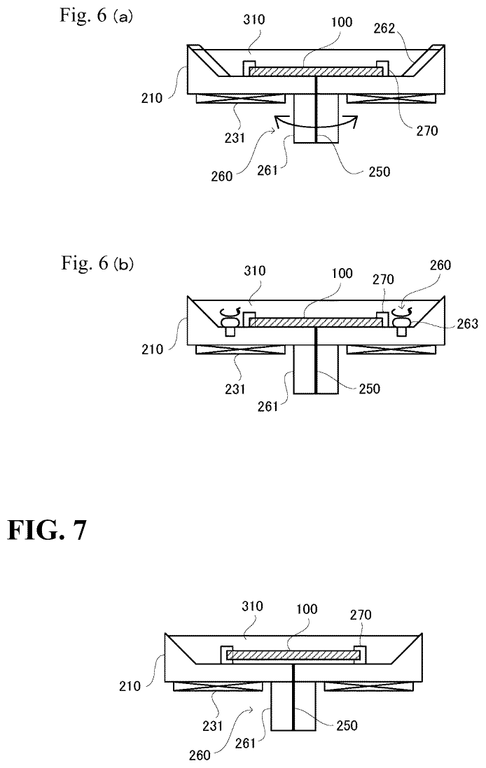

Next, the treatment apparatus 200 according to a modified example of the first embodiment will be described. FIG. 6 (a) and FIG. 6 (b) are schematic cross-sectional views illustrating a stirring device 260 of a first modified example and a second modified example, respectively.

The stirring device 260 of the first modified example illustrated in FIG. 6 (a) has a rotating device 261 as described above, and further has a convex portion (fin) 262 provided in the container 210. The convex portion 262 is a member that projects into the container 210 from a side surface or a bottom surface of the container 210. In a driving of the rotating device 261 during stirring (reversal of a rotation direction or intermittent rotation in one direction), when the rotation of the container 210 is interrupted, the etching liquid 310 tends to continue moving due to inertia. The stirring device 260 of this modified example can stir the etching liquid 310 more efficiently by disturbing a flow of the etching liquid 310 that tends to continue moving due to inertia, by the convex portion 262. The stirring device 260 of the first modified example is an example of the stirring device 260 that stirs the etching liquid 310 by moving the container 210.

The stirring device 260 of the second modified example illustrated in FIG. 6 (b) is an example of the stirring device 260 having a stirrer 263 provided in the container 210, for stirring the etching liquid 310 by moving a stirring member in the etching liquid 310. The stirrer 263 is preferably attached to the container 210 so that it is not discharged together with the etching liquid 310 when the etching liquid 310 is discharged from the container 210.

FIG. 7 is a schematic cross-sectional view illustrating a fixing device 270 according to a modified example. The fixing device 270 of this modified example is a fixing device 270 configured to fix the object to be treated 100, with the bottom surface (at least a part of) of the object to be treated 100 separated from the bottom surface in the container 210. The fixing device 270 of this modified example has, for example, a portion sandwiched between the bottom surface of the object to be treated 100 and the bottom surface in the container 210, to thereby separate the bottom surface of the object to be treated 100 from the bottom surface in the container 210.

As described with reference to FIG. 4 (a), when the etching target 10 comprises a member having conductivity in a total thickness, that is, when the bottom surface of the object to be treated 100 (the surface opposite to the surface irradiated with light 225) is a conductive surface electrically connected to the region to be etched 20, the fixing device 270 of this modified example is preferably used. Thereby, PEC etching can be performed with the region to be etched 20 and the bottom surface of the object to be treated 100 in contact with the etching liquid 310. That is, the bottom surface of the object to be treated 100 can be used as a cathode region.

### Experimental Example of the First Embodiment

Next, an experimental example relating to thermal PEC etching will be described. In this experimental example, PEC etching was performed by placing a beaker on a hot plate (heater), storing the etching liquid and the object to be treated in the beaker, and irradiating the object to be treated with light while heating the etching liquid with a hot plate.

The object to be treated has an etching target (wafer) and a mask similar to the structure illustrated in FIG. 4 (a). However, no cathode pad is formed. A laminated substrate in which a GaN layer was epitaxially grown on a GaN free-standing substrate was used as the etching target. The mask comprises silicon oxide.

Specifically, the object to be treated was prepared as follows. A laminated substrate was prepared by growing a GaN layer (intermediate layer), which is an n+ type layer with a thickness of 2 μm, by organic metal vapor phase growth (MOVPE) on an n-type GaN free-standing substrate with a diameter of 2 inches manufactured by a void formation peeling (VAS) method, and by growing a GaN layer (drift layer) with a thickness of 13 m and a Si concentration of 0.9×10¹⁶/cm³ on the GaN layer (intermediate layer). A mask was formed by depositing a silicon oxide layer with a thickness of 330 nm on the GaN layer (drift layer) and patterning the silicon oxide layer. The laminated substrate on which the mask was formed was cut into small pieces of about 6 mm square, and the small pieces were used as objects to be treated.

An ammonium peroxodisulfate ((NH₄)₂S₂O₈) aqueous solution was used as the etching liquid. Hereinafter, the S₂O₈²⁻ concentration (concentration at the time of preparation) in the etching liquid may be simply referred to as a concentration. In this experimental example, two types of etching liquids having two concentrations of 0.025 mol/L (M) and 0.25 mol/L (M) were used.

The placement depth L of the object to be treated in the etching liquid was 10 mm. Further, in order to contact the bottom surface of the object to be treated with the etching liquid and use it as a cathode region, the object to be treated was placed, with 0.4 mm thick sapphire piece sandwiched between the bottom surface of the object to be treated and the bottom surface of the beaker, and in a state where the bottom surface of the object to be treated is separated from the bottom surface of the beaker.

The etching liquid in the beaker was heated by the hot plate. The temperature of the etching liquid was measured with a thermocouple, and the hot plate was controlled based on a measurement result of the thermocouple. Further, in order to suppress a temperature unevenness of the etching liquid, the etching liquid was stirred at 200 rpm by the stirrer placed in the beaker.

Light irradiation was performed from above using a manual mask aligner device (Union Optical, PEM-800) for a diameter of 4 inches. A high-pressure mercury lamp (Ushio Denki, USH-350D) was used as a light source. An irradiation intensity (power density) on the surface of the etching liquid was 15.9 mW/cm² at a wavelength of 365 nm and 2.13 mW/cm² at a wavelength of 254 nm.

Changes in the pH of the etching liquid over time was measured by a pH meter (Horiba Seisakusho, LAQUAtwin). Further, an etching depth was measured using a surface profiler (Sloan, Dektak3 ST).

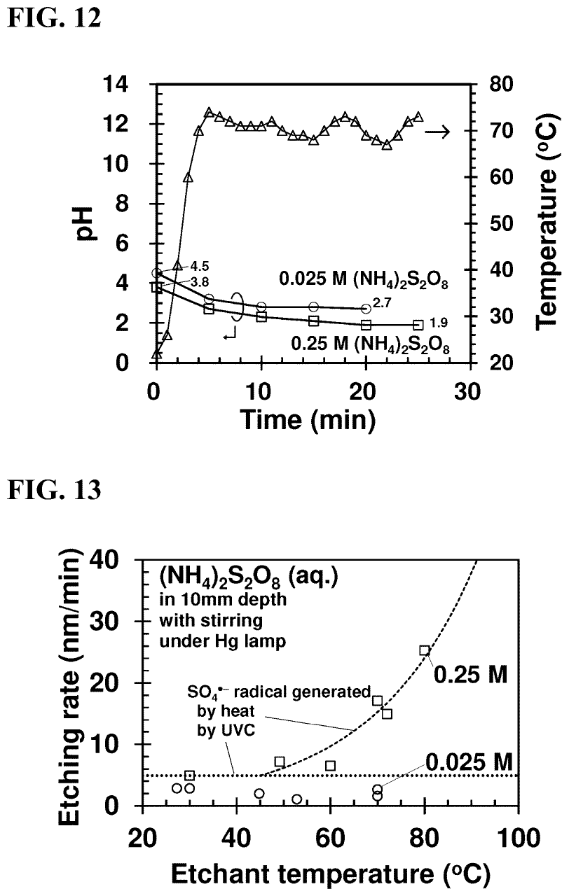

FIG. 12 is a graph showing changes in the temperature and pH of the etching liquid over time in this experimental example. In the example shown in FIG. 12, the liquid temperature is heated from room temperature to 70° C. It is considered that the reason why the fluctuation of the liquid temperature is large in the vicinity of 70° C. is that an amount of the etching liquid used in this experimental example was small.

The (NH₄)₂S₂O₈ aqueous solution is acidic at room temperature regardless of a concentration. Both of the two types of etching liquids with concentrations of 0.025 M and 0.25 M have a lower pH (increased acidity), as the liquid temperature rises from room temperature to 70° C., and even after the liquid temperature becomes almost constant at 70° C. Since the pH drops after the liquid temperature reaches 70° C., it is found that SO₄^{-*} is generated at 70° C.

In this experimental example, an etching rate was measured for each of the two types of etching liquids having concentrations of 0.025 M and 0.25 M, with various liquid temperatures (etching temperatures). After the liquid temperature reached a predetermined temperature, PEC etching was performed for 5 minutes from the time when light irradiation to the region to be etched was started (when PEC etching was started at a timepoint of satisfying both points that the liquid temperature is a predetermined temperature and the region to be etched is irradiated with light), then, an etching depth was measured. Based on the measured etching depth, an average etching rate for 5 minutes was obtained. Thus, in the present specification, the etching rate is defined in the PEC etching for 5 minutes from the start.

FIG. 13 is a graph showing the relationship between the temperature of the etching liquid (etching temperature) and the etching rate in this experimental example. The etching rate at a concentration of 0.025 M is indicated with a circular plot, and the etching rate at a concentration of 0.25 M is indicated with a square plot.

The light emitted to the object to be treated (and the etching liquid) in this experimental example has a component of a wavelength of 254 nm with an intensity of 2.13 mW/cm². Therefore, in this experimental example, PEC etching due to photoradical generation occurs even in a low temperature range where PEC etching due to thermal radical generation hardly occurs. PEC etching due to photoradical generation may be referred to as photoradical PEC etching.

The etching rate at a concentration of 0.25 M tends to increase as the liquid temperature increases. In contrast, the etching rate at a concentration of 0.025 M tends not to increase even when the liquid temperature rises, and is rather decreased at 45° C., 53° C., and 70° C., compared with the etching rate at 30° C. (room temperature).

At a concentration of 0.25 M, the liquid temperature at which the etching rate begins to increase is about 45° C. Further, at a concentration of 0.025 M, a decrease in the etching rate from the etching rate at 30° C. (room temperature) is observed at a point of 45° C. or higher. When considering these results comprehensively, it is understood that an effect of thermal radical generation on the etching rate becomes remarkable in a temperature range where the liquid temperature is 45° C. or higher, and in contrast, the etching rate is substantially determined by photoradical generation, in a temperature range where the liquid temperature is less than 45° C. That is, it is understood that the temperature range of the liquid temperature, which is preferable for the thermal PEC etching, is 45° C. or higher. The temperature range of 45° C. or higher (the temperature range indicated by “by heat” in FIG. 13) may be referred to as a thermal PEC etching region, and the temperature range of less than 45° C. (the temperature range indicated by “by UVC” in FIG. 13) may be referred to as a photoradical PEC etching region.

The etching rate due to photoradical generation at 30° C. (room temperature) is referred to as a reference etching rate. The reference etching rate at a concentration of 0.025 M is 3 nm/min, and the reference etching rate at a concentration of 0.25 M is 5 nm/min.

At a concentration of 0.025 M, the etching rate does not increase with respect to a reference etching rate, but rather tends to decrease. Although the reason therefore is not clear, this reveals that it is not preferable that the concentration of the etching liquid is too low from a viewpoint of increasing the etching rate by heating.

An increase in the etching rate with respect to a reference etching rate cannot be obtained by heating, and this is called deactivation (of the etching liquid). From the viewpoint of increasing the etching rate by heating, the concentration of the etching liquid is preferably a high concentration that does not cause deactivation (that is, a concentration that increases the etching rate by heating).

At a concentration of 0.25 M, an increase in the etching rate with respect to a reference etching rate is obtained by heating. That is, the concentration of 0.25 M is a high concentration that does not cause inactivation. From a temperature-dependent tendency obtained at a concentration of 0.25 M, it can be said that a high etching rate of 6 nm/min at 50° C., 10 nm/min at 60° C., 15 nm/min at 70° C., 20 nm/min at 75° C., and 25 nm/min at 80° C. can be obtained, while the reference etching rate at 30° C. is 5 nm/min.

As described above, when considering the temperature dependence of the etching rates of 0.025 M and 0.25 M comprehensively, a boundary temperature at which the effect of thermal radical generation on the etching rate is remarkable, is considered to be 45° C. The liquid temperature in the thermal PEC etching is preferably 45° C. or higher, and preferably 50° C. or higher from the viewpoint of increasing the etching rate (at a concentration that does not deactivate). Further, when focusing on the temperature dependence of the etching rate at a concentration of 0.25 M, the increase in the etching rate becomes remarkable at 60° C. or higher. Therefore, from the viewpoint of increasing the etching rate, the liquid temperature in the thermal PEC etching is more preferably 60° C. or higher, further preferably 70° C. or higher.

From a viewpoint of suppressing evaporation or boiling of the etching liquid, the liquid temperature is preferably less than 100° C., more preferably 95° C. or lower.

The high concentration that does not cause inactivation is more specifically defined as follows. The high concentration that does not cause inactivation is such that the etching rate for the etching performed using the etching liquid having the above high concentration and heated to 50° C. or higher (or 60° C. or higher, or 70° C. or higher), is higher than the etching rate for the etching performed using the etching liquid having the above concentration and heated to 30° C. (room temperature).

In the etching at a concentration of 0.25 M, 5 nm/min was obtained as a reference etching rate at 30° C., and by heating to 50° C. or higher, an etching rate of 6 nm/min or more (preferably 10 nm/min or more, more preferably 15 nm/min or more, still more preferably 20 nm/min or more, still more preferably 25 nm/min or more) exceeding the reference etching rate is obtained. Therefore, a preferable high concentration for increasing the etching rate may be defined as follows. The concentration is high enough to increase the etching rate to 6 nm/min or more (preferably 10 nm/min or more, more preferably 15 nm/min or more, still more preferably 20 nm/min or more, still more preferably 25 nm/min or more) in the etching performed using the etching liquid having the above high concentration and heated to 50° C. or higher.

It is a finding newly obtained by the inventors of the present application that, for example, the etching rate of at least 6 nm/min or more (preferably 10 nm/min or more, more preferably 15 nm/min or more, still more preferably 20 nm/min or more, still more preferably 25 nm/min or more) can be obtained by thermal PEC etching. Further, for example, it is also a finding newly obtained by the inventor of the present application that, for example, the etching rate of 6 nm/min or more cannot be obtained at a low concentration of 0.025 M by the thermal PEC etching.

The concentration of 0.025 M is a low concentration that causes inactivation, and in order to suppress the inactivation, the concentration is preferably more than 0.025 M. Here, in the experiment described with reference to FIG. 11, as described above, the radical generation rate in the acidic region (x in acid) is as follows. The radical generation rate by heat at 70° C. at a S₂O₈²⁻ concentration of 0.075 mol/L (1.71×10⁻⁴ (mol/L)/min) exceeds the radical generation rate by light at room temperature at a S₂O₈ concentration of 0.025 mol/L (1.54×10⁻⁴ (mol/L)/min). When considering this fact, it is expected that deactivation can be suppressed by setting the concentration to, for example, 0.075 mol/L or more. From the viewpoint of increasing the etching rate by thermal PEC etching, the concentration of the etching liquid (S₂O₈²⁻ concentration) is preferably 0.075 mol/L (M) or more, more preferably 0.1 mol/L (M) or more, more preferably 0.15 mol/L (M) or more, further preferably 0.2 mol/L (M) or more, and further preferably 0.25 mol/L (M) or more.

In this experimental example, the light applied to the object to be treated also contains a component of a wavelength of less than 310 nm (specifically, a wavelength of 254 nm) (for example, at an intensity of 0.5 mW/cm² or more, and for example, at an intensity of 1 mW/cm² or more), and therefore photoradical PEC etching also occurs. It can be said that the reference etching rate of 5 nm/min in the etching at a concentration of 0.25 M is caused by photoradical PEC etching.

Increasing the etching rate by photoradical PEC etching is not easy as described below. In order to increase the etching rate by photoradical PEC etching, for example, it is conceivable to increase the irradiation intensity of a wavelength component of a wavelength of less than 310 nm. However, even when the irradiation intensity of the wavelength component is increased, it is not easy to increase the photoradical generation in the vicinity of the object to be treated. This is because since the light having the above wavelength component is absorbed and attenuated in the etching liquid through which the light transmits to reach the object to be treated, it is difficult to increase the irradiation intensity in the vicinity of the object to be treated.

In order to increase the etching rate by photoradical PEC etching, for example, it is conceivable to increase the concentration of the etching liquid. However, since the light absorption in the etching liquid as described above increases as the concentration of the etching liquid increases, it is difficult to increase the irradiation intensity in the vicinity of the object to be treated even when the concentration of the etching liquid is increased.

For example, although the concentration of 0.25 M is 10 times the concentration of 0.025 M, the etching rate at the concentration of 0.25 M is less than twice the etching rate at the concentration of 0.025, at a temperature of 30° C. where photoradical PEC etching is considered dominant.

Thus, in the photoradical PEC etching region at less than 45° C., it can be said that the method of increasing the etching rate by increasing the irradiation intensity or increasing the concentration of the etching liquid is not efficient. That is, in the photoradical PEC etching region, it is difficult to efficiently extract a potential SO₄^{-*} generation capacity of a high-concentration etching liquid, and due to such a fact, it is difficult to increase the etching rate.

In contrast, in the thermal PEC etching region of 45° C. or higher, since it is possible to efficiently extract the potential SO₄^{-*} generation capacity of the high-concentration etching liquid., it is easy to increase the etching rate. The reason is considered as follows. It is more efficient to increase the generation of SO₄^{-*} by increasing the liquid temperature in the vicinity of the object to be treated. In the etching at a concentration of 0.25 M, for example, a high etching rate of about 25 nm/min, which is 5 times the reference etching rate is obtained at a temperature of 80° C.

An indication for efficiently obtaining a higher etching rate by thermal PEC etching compared to photoradical PEC etching is defined for example as follows. Obtaining the efficiently higher etching rate by thermal PEC etching compared to photoradical PEC etching, means that the etching rate due to generation of SO₄^{-*} by heating the etching liquid is larger than the etching rate (reference etching rate) due to generation of SO₄^{-*} by irradiation with light having a wavelength component of a wavelength of (200 nm or more) and less than 310 nm

In other words, it can be also said that obtaining the etching rate of more than twice (the reference etching rate) of photoradical PEC etching by thermal PEC etching, means that a higher etching rate is efficiently obtained by thermal PEC etching as compared with photoradical PEC etching. When obtaining the etching rate of more than twice the reference etching rate by photoradical PEC etching using the etching liquid having the same concentration, the irradiation intensity is required to be increased.

However, as described above, it is inefficient to increase the etching rate by increasing the irradiation intensity. Therefore, a situation where the high etching rate, which is more than twice the reference etching rate, is obtained by thermal PEC etching, is one of the indications that a high etching rate is efficiently obtained by thermal PEC etching compared with photoradical PEC etching.

For example, at a concentration of 0.25 M, it can be said that an etching rate of more than 10 nm/min can be obtained in the etching at a liquid temperature of more than 60° C. Also, it can be said that a difference between this etching rate and the reference etching rate 5 nm/min by photoradical PEC etching is “the etching rate due to generation of SO₄^{-*} by heating the etching liquid”. The difference is more than 5 nm/min, which is larger than “5 nm/min that is the etching rate (reference etching rate) due to generation of SO₄^{-*} by emitting light having a wavelength component of (200 nm or more) and less than 310 nm”. Therefore, it can be said that a higher etching rate is efficiently obtained as compared with photoradical PEC etching, in the thermal PEC etching at a liquid temperature of more than 60° C. with a concentration of 0.25 M.

When performing thermal PEC etching, the light applied to the object to be treated (and the etching liquid) may or may not have a component of a wavelength of (200 nm or more) and less than 310 nm. According to the thermal PEC etching, PEC etching can be performed even by using a light that does not have the above component. In the thermal PEC etching, the irradiation intensity of the light emitted to the etching liquid and having a predetermined wavelength in a wavelength range of (200 nm or more) and less than 310 nm, may be 3 mW/cm² or less. In this experimental example, the irradiation intensity of the light emitted to the etching liquid and having a wavelength of 254 nm, is 2.13 mW/cm².

In the thermal PEC etching, as described above, since it is possible to efficiently extract the potential SO₄^{-*} generation capacity of a high-concentration etching liquid, it is easy to increase the etching rate. However, when the intensity of the light emitted to the region to be etched is constant, a hole generation rate will be constant. Accordingly, when the SO₄^{-*} generation rate is so high that there are not enough holes for SO₄⁻*, it is considered that the etching rate cannot be further increased. A maximum value of such an etching rate is referred to as a hole rate-determining etching rate.

In the thermal PEC etching region, when the etching rate reaches the hole rate-determining etching rate, it is considered that the etching rate does not increase even when the concentration of the etching liquid is increased. It can be said that a high concentration that is close to the hole rate-determining etching rate and enables to obtain a high etching rate, is a concentration at which holes can be used efficiently.

However, since the etching rate in the thermal PEC etching region is low on a low temperature side and high on a high temperature side, it is considered that the hole rate-determining etching rate is satisfied at a certain high temperature. Here, a high concentration that almost reaches the hole rate determining etching rate at 70° C. is considered to be a concentration at which holes can be used efficiently. In such an etching with a high concentration, it can be said that the etching rate at a temperature of 70° C. or higher, for example, 80° C., remains at the same level as the etching rate at 70° C., for example, remains at 1.2 times or less.

Based on such a consideration, in the thermal PEC etching, a high concentration of the etching liquid at which a high etching rate close to the hole rate-determining etching rate can be obtained (concentration at which holes can be efficiently used), is defined as follows, for example. The concentration at which holes can be used efficiently, is a (high) concentration at which the etching rate in the etching performed using the etching liquid having the above concentration and heated to 80° C. is 1.2 times or less the etching rate in the etching performed using the etching liquid having the above concentration and heated to 70° C.

At a concentration of 0.25 M, the ratio of 25 nm/min, which is the etching rate at 80° C., with respect to 15 nm/min, which is the etching rate at 70° C., is 1.7 times. Accordingly, it can be said that the concentration at which the holes can be efficiently used, which is defined as described above, is a concentration exceeding 0.25 M.

In the thermal PEC etching, the etching rate may be controlled by changing the light irradiation intensity for generating holes, while keeping the concentration and temperature of the etching liquid constant. It is preferable that the light for irradiating the object to be treated (and the etching liquid) does not have a component of a wavelength of (200 nm or more) and less than 310 nm

In this experimental example, an ammonium peroxodisulfate ((NH₄)₂S₂O₈) aqueous solution was used as a salt of S₂O₈²⁻ for preparing the etching liquid. The solubility of (NH₄)₂S₂O₈ in water at room temperature is 1.95 mol/L (80 g/100 mL, MW=228.18 g/mol).

In the etching liquid for thermal PEC etching, that is, the etching liquid heated to the etching temperature, it is preferable that the salt of S₂O₈²⁻ is not precipitated (not undissolved), for example, to suppress the inhibition of etching due to the precipitation (remaining undissolved) salt adhering to the region to be etched. Even in the etching liquid at room temperature (20° C. or higher and 30° C. or lower), it is more preferable that the salt of S₂O₈²⁻ is not precipitated (not left undissolved), to facilitate the preparation of the etching liquid.

If necessary, the salt of S₂O₈²⁻ may be precipitated (remains undissolved) in the etching liquid heated to the etching temperature. That is, a saturated aqueous solution of the salt may be used as the etching liquid. Thereby, the concentration of the etching liquid can be kept constant over time at a saturated concentration.

Other salts of (NH₄) ₂S₂O₈, such as potassium peroxodisulfate (K₂S₂O₈), may be used, or for example, sodium peroxodisulfate (Na₂S₂O₈) may be used, as the salt of S₂O₈²⁻ for preparing the etching liquid. The solubility of K₂S₂O₈ in water at room temperature is 0.18 mol/L (5.2 g/100 mL, MW=270.33 g/mol). The solubility of Na₂S₂O₈ in water at room temperature is 1.5 mol/L (55.6 g/100 mL, MW=238.10 g/mol).

For example, when using thermal PEC etching as part of a step for manufacturing a semiconductor device, it may be desired to avoid residual alkali metal elements. In such a case, it is preferable to use a salt containing no alkali metal such as (NH₄) ₂S₂O₈ in the etching liquid rather than using a salt containing an alkali metal element such as K₂S₂O₈ or Na₂S₂O₈ in the etching liquid. It is also preferable to use (NH₄)₂S₂O₈ because of its high solubility in water as compared with, for example, K₂S₂O₈. Due to high solubility of salt, it is difficult for salt to precipitate when the temperature drops in the post-treatment step (cooling step), and therefore it is also possible to prevent the precipitated salt from becoming a residue during washing.

As described above, thermal PEC etching, which is a new technique for PEC etching (electrodeless PEC etching) for group III nitrides, is proposed. By using the thermal PEC etching, it becomes easy to increase the etching rate as compared with, for example, the photoradical PEC etching. Thereby, deep digging such as through hole formation by PEC etching becomes easy. Lift-off is possible by using thermal PEC etching, or, for example, using PEC etching.

Thermal PEC etching is a technique of generating holes by light irradiation and generating SO₄^{-*} by heating. Thereby, the independence of control between the generation of holes and the generation of SO₄^{-*} can be improved, and therefore the controllability of etching conditions such as the etching rate can be improved.

### Other Aspects of the First Embodiment

The first embodiment and its modified examples have been specifically described above. However, the present disclosure is not limited thereto, and various changes, improvements, combinations, and the like can be made without departing from the gist thereof.

For example, the above-described embodiment shows an aspect in which the preliminary heating temperature is less than 45° C., in the heating method (the method of the first example and the method of the second example) in the PEC etching step described with reference to FIG. 2 (b). However, the preliminary heating temperature is not necessarily less than 45° C. and may be appropriately set to a temperature lower than the etching temperature in the thermal PEC etching (set to 45° C. or higher).

Further for example, the above-described embodiment shows an aspect in which a post-treatment step that also serves as a cooling step is performed using an unheated (30° C. or lower) post-treatment liquid, in the post-treatment step described with reference to FIGS. 3 (a) and 3 (b). However, the temperature of the post-treatment liquid that also serves as a cooling step is not essential to be 30° C. or lower, and may be appropriately set to a temperature lower than the etching temperature in the thermal PEC etching (set to 45° C. or higher).

Further for example, in the above-described experimental example, an acidic (NH₄) ₂S₂O₈ aqueous solution was used as the etching liquid from the time of preparation (from the start of etching). As described with reference to (Chemical formula 1), pH of the etching liquid decreases as the PEC etching progresses. Accordingly, when the etching liquid is acidic from the start of etching, the etching liquid remains acidic until the end of etching. That is, the above-described example shows an aspect in which the etching liquid remains acidic during a PEC etching period (this is called acidic region PEC etching).

The PEC etching may be performed in such a manner that the etching liquid is maintained in an alkaline state during the etching period (this is referred to as alkaline region PEC etching). PEC etching progresses by dissolving an oxide of a group III element in an alkaline or acidic etching liquid. Therefore, PEC etching is interrupted during a period in which the etching liquid becomes neutral. Further, when the etching liquid changes from alkaline to acidic, there is a concern that the etching condition may fluctuate over time because the etching condition in an alkaline region and the etching condition in an acidic region are different from each other. From this viewpoint, it is preferable that PEC etching is performed as acidic region PEC etching or as alkaline region PEC etching, as in the above experimental example.

Alkaline region PEC etching is performed, for example, as follows. The etching liquid is prepared as an alkaline etching liquid by mixing an aqueous solution of a salt of S₂O₈²⁻ with an alkaline aqueous solution such as a KOH aqueous solution. When performing alkaline region PEC etching as thermal PEC etching, PEC etching is performed by generating SO₄^{-*} by heating the etching liquid and generating holes by irradiating the region to be etched with light. As the PEC etching progresses, the pH of the etching liquid decreases. Therefore, by adding the alkaline aqueous solution (if necessary) to the etching liquid, the etching liquid may be kept alkaline (to suppress a decrease in pH). For example, by increasing the concentration of the alkaline aqueous solution mixed with the etching liquid, further, for example, by shortening the etching time (one time using the same etching liquid), the state in which the etching liquid is alkaline may be kept without adding the alkaline aqueous solution.

In thermal radical generation, when the pH of the etching liquid is less than 9, it drops sharply and becomes acidic (see FIG. 10). Therefore, in the alkaline region PEC etching, the pH of the etching liquid during the etching period is preferably kept at 9 or more. A range of decrease in pH of the etching liquid from the start of etching (the difference between a maximum pH and a minimum pH during the etching period) is preferably 5 or less because the maximum pH is 14. Further, the range of decrease is more preferably 4 or less, and further preferably 3 or less, from a viewpoint of suppressing the fluctuation of an etching condition. The pH at the time of starting thermal PEC etching is preferably high, preferably 11 or more, more preferably 12 or more, and further more preferably 13 or more, from a viewpoint of making it difficult to acidify the pH of the etching liquid.

For example, the pH of a mixed solution obtained by mixing a KOH aqueous solution having a concentration of xmol/L (M) with a K₂S₂O₈ aqueous solution having a concentration of 0.05 mol/L (M) at a ratio of 1:1 is as follows. The pH of a single K₂S₂O₈ aqueous solution is 3.18. The pH of the mixed solution in which x is 0.001 M, 0.01 M, 0.1 M, and 1 M, is 4.4, 11.9, 13.0, and 13.9, respectively.

As illustrated in FIG. 11, a radical generation rate in the mixed solution heated to 70° C. is higher in the alkaline region than in the acidic region. This result shows that by performing thermal PEC etching as the alkaline region PEC etching, it is expected that a higher etching rate can be obtained as compared with a case where the thermal PEC etching is performed as the acidic region PEC etching.

It is preferable that the etching liquid is kept acidic or alkaline during the etching period, from a viewpoint of suppressing the time fluctuation of the etching condition. However the etching liquid at least at the start of etching may be alkaline from the viewpoint of improving the etching rate at least in the period near the start of etching.

### Second Embodiment

Next, a second embodiment will be described. The second embodiment shows an aspect in which the treatment apparatus (etching apparatus) used for the PEC etching step is different from that of the first embodiment. Also, the second embodiment shows an aspect in which a group III nitride semiconductor device 500 is manufactured by PEC etching. Details will be described below.

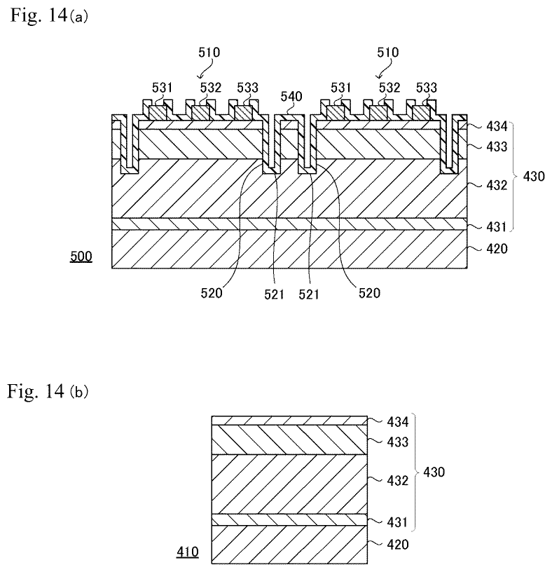

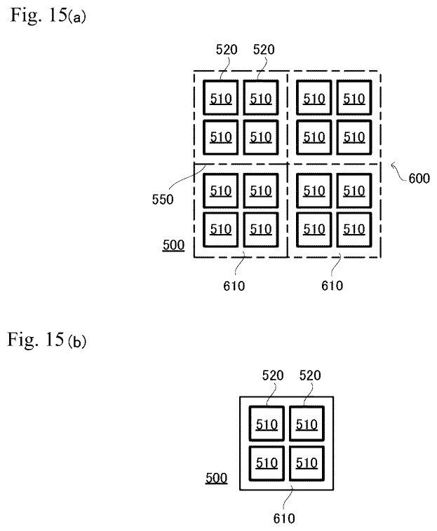

A group III nitride semiconductor device 500 (hereinafter, also referred to as a semiconductor device 500) according to the second embodiment will be described. FIG. 14 (a) is a schematic cross-sectional view of the device 500, and FIG. 14 (b) is a schematic sectional view of a laminated substrate 410 which is a material of the semiconductor device 500. FIG. 15 (a) is a schematic plan view of the semiconductor device 500 shown as an aspect of the wafer 600, and FIG. 15 (b) is a schematic plan view of the semiconductor device 500 shown as an aspect of a chip 610.

The laminated substrate 410 has a substrate 420 and an element forming layer 430 that is provided above the substrate 420 and comprises group III nitride crystal (see FIG. 14 (b)). The semiconductor device 500 has the element forming layer 430 in which a plurality of semiconductor elements 510 are formed, and an element separation groove 520 provided in the element forming layer 430 and separating the semiconductor elements 510 from each other (see FIG. 14 (a)). The element separation groove 520 corresponding to each semiconductor element 510 is formed so as to surround each semiconductor element 510 in a plan view of a top surface of the element forming layer 430 when viewed from a normal direction (see FIGS. 15 (a) and 15 (b)).

The element separation groove 520 according to the present embodiment is formed by etching the element forming layer 430 by photoelectrochemical (PEC) etching. Hereinafter, PEC etching may be simply referred to as etching. A precursor member of the semiconductor device 500 to which PEC etching is performed is referred to as an etching target 450 (hereinafter, also referred to as a target 450). The top surface 455 of the target 450, which is the surface to be subjected to PEC etching, is the top surface of the element forming layer 430, and at least the top surface 455 of the target 450 comprises group III nitride crystal.

Although details will be described later, the element separation groove 520 having the following feature can be formed by performing the above PEC etching while rotating the target 450, by supplying the etching liquid to the target 450 while flowing it at a constant temperature.

The element separation groove 520 has a feature that a flatness of an inner surface is high. Thereby, a leakage current between the semiconductor elements 510 can be suppressed compared with a case where the flatness of the inner surface of the element separation groove 520 is low. Regarding the bottom surface 521, the height of the flatness of the inner surface is typically evaluated as follows. The bottom surface 521 of the element separation groove 520 has a root mean square (RMS) surface roughness of 1 nm or less in a region out of a 5 μm square region observed with an atomic force microscope (AFM), which is the region excluding a position of a through dislocation of the group III nitride crystal constituting the element forming layer 430. As described above, the portion of the through dislocation is difficult to be etched in PEC etching. Therefore, if necessary, flattening etching as described above may be preferably performed as a post-treatment in the PEC etching.

Further, the element separation groove 520 has a feature that damage to the group III nitride crystal due to etching when forming the element separation groove 520 is hardly caused on the inner surface. Thereby, for example, it is possible to suppress an isolation leak when operating the high electron mobility transistor (HEMT) as the semiconductor element 510.

Regarding the bottom surface 521, a small amount of damage caused by etching on the inner surface is typically evaluated as follows. A band edge peak intensity of a photoluminescence (PL) emission spectrum at the bottom surface 521 of the element separation groove 520, has an intensity of 90% or more with respect to a band edge peak intensity of a PL emission spectrum on a top surface (that is, a surface not subjected to etching) of the element forming layer 430.

Hereinafter, a configuration example of the semiconductor device 500 will be described more specifically. The substrate 420 is a base substrate for growing group III nitride crystal constituting the element forming layer 430, and for example, it may be a heterogeneous substrate comprising a material different from that of the group III nitride, or may be, for example, the same kind of substrate comprising the group III nitride. As the heterogeneous substrate, for example, a silicon carbide (SiC) substrate is used, and for example, a silicon (Si) substrate is used. As a homogenous substrate, for example, a gallium nitride (GaN) substrate is used.

The element forming layer 430 may have various layer configurations depending on a material constituting the substrate 420, a structure of the semiconductor element 510 formed on the element forming layer 430, etc. As the semiconductor element 510, those having various structures may be formed, if necessary. Hereinafter, explanation will be given for an embodiment in which the substrate 420 is a SiC substrate and HEMTs are formed as semiconductor elements 510 on the element forming layer 430. In this example, the substrate 420 may be referred to as a SiC substrate 420, and the semiconductor element 510 may be referred to as a HEMT 510.

The following is exemplified as a layer structure of the element forming layer 430 when the HEMT 510 is formed above the SiC substrate 420. A nucleation layer 431 is formed on the SiC substrate 420, comprising aluminum nitride (AlN). A channel layer 432 is formed on the nucleation layer 431, comprising GaN. A thickness of the channel layer 432 is, for example, 1.2 μm. A barrier layer 433 is formed on the channel layer 432, comprising aluminum nitride gallium (AlGaN). A thickness of the barrier layer 433 is, for example, 24 nm, and a composition of AlGaN in the barrier layer 433 is, for example, Al_{0.22}Ga_{0.78}N. A cap layer 434 is formed on the barrier layer 433, comprising GaN. A thickness of the cap layer 434 is, for example, 5 nm.

The element forming layer 430 of this example has a nucleation layer 431, a channel layer 432, a barrier layer 433, and a cap layer 434. Two-dimensional electron gas (2DEG), which is a channel of HEMT 510, is generated in a laminated portion of the channel layer 432 and the barrier layer 433. As the characteristics obtained by the exemplary element forming layer 430, mobility is, for example, 1940 cm²/Vs, and sheet resistance Rs is, for example, 490 Ω/sq.

The device forming layer 430 may be formed by growing the group III nitride crystal on the substrate 420 by a known method such as metalorganic vapor phase growth (MOVPE). The present embodiment shows an aspect in which by growing the group III nitride crystal constituting the element forming layer 430 with the c-plane as the growth surface, the crystal plane with a lowest index closest to an outermost surface of the element forming layer 430 (in this example, the top surface of the cap layer 434) is the c-plane, and accordingly shows an aspect in which the c-plane of the group III nitride crystal is etched as PEC etching to form the element separation groove 520.

The source electrode 531 and the gate electrode 532 and the drain electrode 533 of each HEMT 510 are formed on the top surface of the element forming layer 430. A protective film 540 is formed over an entire top surface of the semiconductor device 500 so as to have openings on the top surfaces of the source electrode 531 and the gate electrode 532 and the drain electrode 533. The source electrode 531, the gate electrode 532, the drain electrode 533, and the protective film 540 may be formed by a known method.

The element separation groove 520 of this example is provided so that the bottom surface 521 is arranged at a position deeper than the top surface of the channel layer 432, that is, so that the 2DEG is divided by the element separation groove 520. By forming the element separation groove 520 corresponding to each HEMT 510 in a plan view so as to surround each HEMT 510, the 2DEG used as the channel of each HEMT 510 is separated from the 2DEG used as the channel of the adjacent HEMT 510. In this way, the elements are separated.

FIG. 15 (a) is a schematic plan view of the semiconductor device 500 shown as an aspect of the wafer 600, and FIG. 15 (b) is a schematic plan view of the semiconductor device 500 shown as an aspect of a chip 610. The chip 610 has a plurality of arranged semiconductor elements 510, and the semiconductor elements 510 are separated from each other by the element separation groove 520. A layout of the semiconductor element 510 and the element separation groove 520 in the chip 610 may be appropriately changed as necessary. FIG. 15 (a) illustrates a wafer 600 before the chips 610 are separated from each other, and the wafer 600 has a plurality of arranged chips 610. A scribe line 550 is arranged between the chips 610. FIG. 15 (b) illustrates one chip 610 separated from the wafer 600.

Next, a method for forming the element separation groove 520 by PEC etching will be described as an example of a method for manufacturing a structure according to a second embodiment. Further, a PEC etching apparatus 700 (hereinafter, also referred to as an etching apparatus 700) used in the method will be described as an example of a structure manufacturing apparatus according to the second embodiment.

The first embodiment shows an aspect in which by containing the etching target 10 and the etching liquid 310 in the container 210 so that the top surface 101 of the etching object 10 is submerged in the etching liquid 310, an entire top surface 101 of the etching target 10 is immersed in the etching liquid 310, and by rotating the container 210, the etching liquid 310 is rotated together with the etching target 10.

As described below, the second embodiment shows an aspect in which by flowing the etching liquid 800 from a center side of rotation to an outer peripheral side on the top surface 455 of the etching target 450 by rotating the etching target 450 while supplying the etching liquid 800 onto the top surface 455 of the etching target 450 without submerging the top surface 455 of the etching target 450 in the etching liquid 800, an entire top surface 455 of the etching target 450 is immersed in the etching liquid 800.

The etching target 450 (target 450) to which PEC etching is performed by the etching apparatus 700 is a precursor member of the group III nitride semiconductor device 500 (semiconductor device 500). The target 450 can take various forms depending on a procedure for manufacturing the device 500. The target 450 may be, for example, the laminated substrate 410 itself, or may be, for example, a member at a stage where the source electrode 531 and the gate electrode 532 and the drain electrode 533 are formed on the laminated substrate 410.

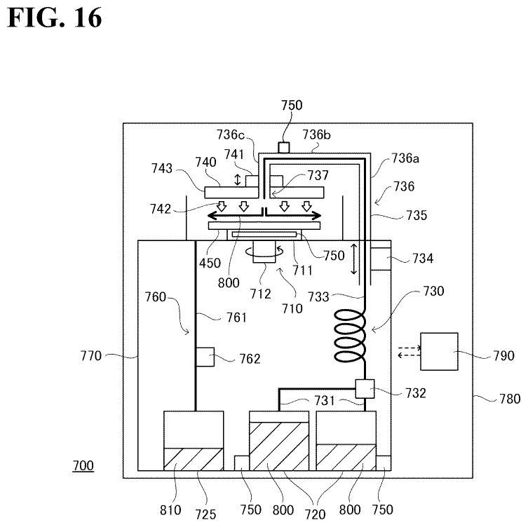

FIG. 16 is a schematic cross-sectional view illustrating the etching apparatus 700 according to the present embodiment. The etching apparatus 700 mainly includes a holding unit 710, a tank 720, a supply unit 730, a light irradiation device 740, a temperature control unit 750, and a control device 790. Other components preferably included in the etching apparatus 700 will be described below as needed. The control device 790 controls the holding unit 710, the supply unit 730, the light irradiation device 740, the temperature control unit 750, etc., so as to perform a predetermined operation.

The holding unit 710 has a holding table 711 and a rotating device 712, and holds the target 450 rotatably. The target 450 is placed on the holding table 711 provided on the top surface of an inner housing 770, and the target 450 can be rotated by the rotating device 712 rotating the holding table 711. The operation of the rotating device 712 is controlled by the control device 790.

Unlike the holding unit 264 of the first embodiment, the holding unit 710 according to the second embodiment does not have to have a container for storing the etching liquid 800 until the liquid surface is arranged at a position higher than the top surface 455 of the target 450, that is, a container configured to make the top surface 455 of the target 450 submerged in the etching liquid 800.

The tank 720 is arranged inside the inner housing 770 (below the holding table 711) and houses the etching liquid 800 supplied to the target 450. FIG. 16 illustrates an embodiment in which the etching apparatus 700 includes two tanks 720. Thereby, when the etching liquid 800 in one tank 720 becomes low, the etching liquid 800 can be supplied by switching the tank 720 so that the etching liquid 800 is supplied from the other tank 720. If necessary, the etching apparatus 700 may include one tank 720 or may include three or more tanks 720.

The supply unit 730 has various members and mechanisms for supplying (flowing) the etching liquid 800 contained in the tank 720 onto the top surface 455 of the target 450. In this example, the supply unit 730 includes a connection pipe 731, a pump and a switching valve 732, a hose 733, a moving mechanism 734, and an arm 735.

The connection pipe 731 connects each of the two tanks 720 to the pump and the switching valve 732. The pump and the switching valve of the switching valve 732 select from which tank 720 the etching liquid 800 is supplied to the target 450. The etching liquid 800 is supplied from the selected tank 720 to the target 450 through the hose 733, through the pump and the pump of the switching valve 732. The operation of the pump and the switching valve 732 is controlled by the control device 790.

On the top surface of the inner housing 770, a movable arm 735 is provided so as to penetrate the inner housing 770 from the inside to the outside (from the lower side to the upper side). The hose 733 is inserted through the arm 735 and moves integrally with the arm 735. A discharge port 737 of the hose 733 is arranged at a tip of the arm 735. When PEC etching is performed, the moving mechanism 734 moves the arm 735 to a predetermined position, to thereby discharge the etching liquid 800 from the discharge port 737 toward the top surface of the target 450, with the discharge port 737 of the hose 733 located at a predetermined position (predetermined height position and horizontal plane position). The operation of the moving mechanism 734 is controlled by the control device 790.

The arm 735 and the hose 733 inserted through the arm 735 are collectively referred to as a pipe 736. The pipe 736 arranged at a predetermined position when the PEC etching is performed, has a portion 736a that transports the etching liquid 800 to an upper part of the target 450 in such a manner as ascending the outside of the target 450. Further, the pipe 736 has a portion 736b that transports the etching liquid 800 that has passed through the portion 736a from the outside to the inside of the target 450 above the target 450. Further, the pipe 736 has a portion 736c that transports the etching liquid 800 that has passed through the portion 736b in such a manner as descending inside the target 450 to discharge the etching liquid 800 from the discharge port 737 toward the target 450. That is, at least a part of the pipe 736 is arranged above the target 450 so as to transport the etching liquid 800 through a region overlapping the target 450 in a plan view viewed from a normal direction of the top surface 455 (top surface of the element forming layer 430) of the target 450 when PEC etching is performed.

The light irradiation device (light emitting unit) 740 has a light source 743, and the light source 743 irradiates the top surface 455 of the object 450 with light 742 which is ultraviolet (UV) light having a wavelength of 365 nm or less. When controlling an amount of SO₄^{-*} radicals generated due to light 742 in the PEC etching, it is preferable to emit light 742 having a component of a wavelength of 200 nm or more and less than 310 nm.

As the light source 743 of the light irradiation device 740, for example, a plasma light emitting light source, an ultraviolet light emitting diode (LED), an ultraviolet laser, an ultraviolet lamp, etc., is preferably used. Here, the plasma light emitting light source means a light source that converts UV light generated by plasma emission into UV light of a predetermined wavelength by a phosphor (for example, a light source that converts vacuum ultraviolet plasma emission from xenon neon (Xe—Ne) into UVC by a magnesium oxide (MgO) phosphor, etc.). As the light source 743 in the present embodiment, a surface light source may be preferably used, and such a surface light source is formed by laying, for example, the ultraviolet LED, the plasma light emitting light source, etc., in a plane shape. As the light source 743, a light source having a variable irradiation output is preferably used. Further, as the light source 743, a light source capable of pulse irradiation and having a variable duty ratio is preferably used. The light source 743 may include a bandpass filter that cuts an unnecessary wavelength range. The irradiation output, duty ratio, etc., of the light irradiation device 740 (light source 743) are controlled by the control device 790.

In this example, the light irradiation device 740 is attached to the arm 735 through an attachment portion 741. The attachment portion 741 supports the light irradiation device 740 so that the light irradiation device 740 can be replaced as needed. It is preferable that the attachment portion 741 supports the light irradiation device 740 so that at least one of a posture (angle) and a height of the light irradiation device 740 is variable. Since the posture of the light irradiation device 740 is variable, the irradiation angle of the light 742 on the target 450 can be adjusted. Further, since the height of the light irradiation device 740 is variable, an irradiation distance (irradiation intensity) of the light 742 to the target 450 can be adjusted. The light irradiation device 740 is arranged, for example, so that a light emitting surface of the light source 743 is parallel to the top surface of the target 450.

In this example, since the light irradiation device 740 is attached to the arm 735, the height of the light irradiation device 740 can also be adjusted by adjusting the height of the arm 735 by the moving mechanism 734. Adjusting the height of the arm 735 by the moving mechanism 734, that is, the height of the discharge port 737 of the hose 733, and adjusting the height of the light irradiation device 740 by the attachment portion 741 can be independently performed, and this is preferable that a discharging condition of the etching liquid 800 and an irradiation condition of the light 742 can be adjusted independently.

The etching apparatus 700 has a temperature control unit 750 that adjusts (heats or cools) the etching liquid 800 supplied to the target 450, to a predetermined temperature. An amount of SO₄^{-*} radicals generated involved in PEC etching depends not only on the irradiation condition of the light 742 but also on the temperature of the etching liquid 800. Therefore, it is preferable that the temperature of the etching liquid 800 is properly controlled. The temperature control unit 750 may be provided at an appropriately selected place such as the tank 720, the pipe 736, the holding table 711, etc.

By supplying the etching liquid 800 to the top surface of the target 450, with the target 450 rotated and irradiating the top surface of the target 450 with the light 742, PEC etching is performed to form the element separation groove 520 on the element forming layer 430.

The etching liquid 800 supplied toward the target 450 flows from the center side of rotation to the outer peripheral side along the top surface of the target 450, then, flows down onto the top surface of the inner housing 770 and is collected in the collection tank 725 through the collection unit 760. The recovery unit 760 has a recovery hose 761 and an etching liquid monitor 762. A hole for collecting the etching liquid is provided on the top surface of the inner housing 770, and an upper end of the recovery hose 761 is connected to the hole, and a lower end of the recovery hose 761 is connected to the recovery tank 725. By measuring pH of the recovered etching liquid 810 flowing through the recovery hose 761, the etching liquid monitor 762 detects the degree of deterioration of the recovered etching liquid 810. Data indicating a detection result by the etching liquid monitor 762 is input to the control device 790.

In the control device 790, when the recovered etching liquid 810 recovered in the recovery tank 725 increases to a predetermined amount (that is, when the etching liquid 800 remaining in the tank 720 currently in use is reduced to a predetermined amount), or when the degree of deterioration of the recovered etching liquid 810 detected by the etching liquid monitor 762 reaches a predetermined degree, the tank 720 that supplies the etching liquid 800 is switched. Two recovery tanks 725 may also be prepared, and the recovery tank 725 may be switched at the timing of switching the tank 720 for supplying the etching liquid 800. When the deterioration of the recovered etching liquid 810 is small enough to have no problem with an etching quality, the recovered etching liquid 810 may be supplied in a cyclical manner so as to be reused as the etching liquid 800 supplied to the target 450.

The etching apparatus 700 is accompanied by irradiation of light 742, which is UV light, from the light irradiation device 740 at the time of PEC etching. It is desirable to prevent the light 742 from leaking to the outside of the etching apparatus 700, from a viewpoint of enhancing the safety of an operator. Therefore, in this example, an outer housing 780 is provided on the outside of the inner housing 770 so that the light irradiation device 740, etc., is housed, using a material that prevents a transmission of the light 742.

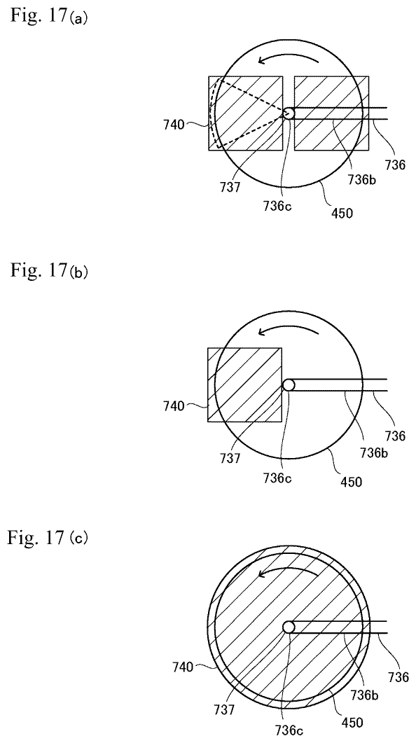

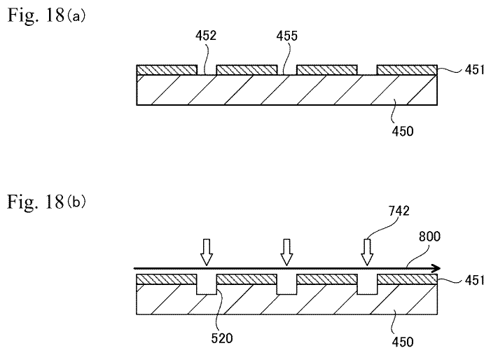

FIG. 17 (a) is a schematic plan view of the etching apparatus 700 illustrated in FIG. 16, in the vicinity of the target 450, and illustrates an approximate positional relationship between the pipe 736 and the light irradiation device 740 when PEC etching is performed. The light irradiation device 740 is shown by hatching that rises to the right.

The discharge port 737 (of the hose 733) of the pipe 736 is located at the center of the target 450 (ie, the center of rotation), and discharges the etching liquid 800 toward the center of rotation of the target 450. Thereby, it is possible to generate a uniform flow of the etching liquid 800 over an entire top surface of the target 450 from the central portion to the outer peripheral portion of the rotating target 450, and in-plane uniformity of the PEC etching can be improved.

The light irradiation device 740 is arranged around the discharge port 737 at a position where it overlaps with the target 450. Thereby, the top surface of the target 450 can be irradiated with the light 742 from the light irradiation device 740, from a direction close to vertical (with a small incident angle) with a short irradiation distance. Accordingly, the light irradiation device 740 is arranged at a position where it does not overlap with the target 450, and it is easy to progress the PEC etching straight in a normal direction of the element forming layer 430, and a decrease in irradiation intensity (unnecessarily expanding of the irradiation area) is suppressed, compared to a mode of irradiating light from an oblique direction (at a large incident angle) with a long irradiation distance.

As described above, in the present embodiment, the discharge port 737 and the light irradiation device 740 are arranged at positions that overlap with the target 450 in a plan view. Thereby, the etching liquid 800 can be satisfactorily supplied from the discharge port 737 toward the target 450, and the target 450 can be satisfactorily irradiated with light from the light irradiation device 740.

The pipe 736 supplies the etching liquid 800 to the target 450 from above, and the light irradiation device 740 irradiates the target 450 with the light 742 from above. Further, as described above, the pipe 736 transports the etching liquid 800 through the region overlapping with the target 450 in a plan view. Therefore, there is a concern that a shadow of the pipe 736 due to the light 742 (particularly, a portion 736b that transports the etching liquid 800 from the outside to the inside of the target 450, and a portion 736c that transports the etching liquid 800 downward inside of the object 450 and discharges it from the discharge port 737) will be reflected on the top surface of the target 450. The formation of such a shadow hinders a progress of PEC etching and hinders an efficient irradiation of light 742.

Therefore, in the present embodiment, the pipe 736 is arranged at a position where the shadow of the pipe 736 due to the light 742 emitted from the light irradiation device 740 is not reflected on the top surface of the target 450. For example, the portion 736b that transports the etching liquid 800 from the outside to the inside of the target 450 is arranged above the light irradiation device 740 (light source 743). That is, the pipe 736 is arranged so as to pass above the light irradiation device 740. Thereby, the shadow of the portion 736b of the pipe 736 is suppressed from being reflected on the top surface of the target 450. Also, thereby, while suppressing such a shadow, the portion 736b of the pipe 736 and the light irradiation device 740 can be arranged so as to be overlapped with each other in a plan view, and therefore the degree of freedom in arranging the pipe 736 and the light irradiation device 740 is improved.

Further for example, the portion 736c that transports the etching liquid 800 in such a manner as descending inside of the target 450 to discharge it from the discharge port 737, particularly the discharge port 737, is arranged at a position that does not overlap with the light irradiation device 740 in a plan view. Thereby, the shadow of the discharge port 737 is suppressed. By emitting the light 742 to some extent from the light irradiating device 740, the region can be irradiated with light directly below the discharge port 737 on the top surface of the object 450.

Further, by arranging the discharge port 737 at a position that does not overlap with the light irradiation device 740, it is possible to prevent the light irradiation device 740 from interfering with the operation of discharging the etching liquid 800 from the discharge port 737. That is, in the present embodiment, the light irradiation device 740 is arranged at a position that does not interfere with a discharging operation of the etching liquid 800 from the discharge port 737.

It is preferable that the light irradiation device 740 is arranged up to a position protruding outside the object 450 in a plan view. Thereby, light irradiation can be appropriately performed up to an edge of the target 450.

The light irradiation device 740 may be arranged in a part (but not all) of the target 450 in a circumferential direction in a plan view. Since the etching apparatus 700 of the present embodiment emits light while rotating the target 450, an entire circumference can be irradiated when the target 450 rotates, even when the light irradiation device 740 is arranged so as to irradiate only a part in the circumferential direction when the target 450 is stationary. When irradiating a part of the target 450 with light so that the integrated irradiation intensity for the target 450 is uniform in the plane, it is desirable that the light irradiation device 740 (light source 743) is arranged so that a light irradiation surface has a fan shape, with a center of rotation of the target 450 as a pivot (see the broken line in FIG. 17 (a)).

FIG. 17 (b) is a first modified example illustrating another arrangement of the light irradiation device 740. The light irradiation device 740 of the embodiment illustrated in FIG. 17 (a) exemplifies an aspect in which the light irradiation devices 740 are arranged on both sides of the discharge port 737 in a plan view. The first modified example exemplifies an aspect in which the light irradiation device 740 is arranged on one side of the discharge port 737 in a plan view. In the aspect of FIG. 17 (b), the pipe 736 is arranged at a position that does not overlap with the light irradiation device 740 in a plan view. Therefore, it is also possible to prevent the above-described shadow from being reflected while preventing the pipe 736 from passing above the light irradiation device 740.

FIG. 17 (c) is a second modified example illustrating still another arrangement of the light irradiation device 740. The light irradiation device 740 of the embodiment illustrated in FIG. 17 (a) exemplifies an aspect in which the light irradiation device 740 is arranged in a part of a circumferential direction of the target 450 in a plan view. The second modified example exemplifies an aspect in which the light irradiation device 740 is arranged in an entire circumferential direction of the target 450 in a plan view.

The mechanism of PEC etching of the group III nitride is also the same in the second embodiment, as that described in the first embodiment. For example, a mixture of an aqueous solution of potassium hydroxide (KOH) and an aqueous solution of potassium persulfate (K₂S₂O₈) (containing hydroxide ion (OH⁻) and peroxodisulfate ion (S₂O₈²⁻)), is used as the etching liquid 800. Such an etching liquid 800 is prepared, for example, by mixing a 0.01 M KOH aqueous solution and a 0.05 M K₂S₂O₈ aqueous solution at a ratio of 1:1. The concentration of OH⁻ and the concentration of S₂O₈²⁻ may be appropriately changed as necessary.

As the alkaline solution used for PEC etching, a sodium hydroxide (NaOH) aqueous solution, etc., may be used in addition to the KOH aqueous solution. An acidic solution may be used for PEC etching, and a phosphoric acid (H₃PO₄) aqueous solution, etc., may be used as the acidic solution.

As illustrated in (Chemical formula 2), as a method for generating SO₄^{-*} radicals from S₂O₈², at least one of the irradiation with light 742 and heating can be used. When irradiation with light 742 is used, in order to increase the light absorption by S₂O₈²⁻ and efficiently generate SO₄^{-*} radicals, the wavelength of the light 742 is preferably 200 nm or more and less than 310 nm.

The temperature control unit 750 may be used to keep the temperature of the etching liquid 800 constant so that a fluctuation of an amount of SO₄^{-*} radicals generated due to the temperature fluctuation of the etching liquid 800 is suppressed. When controlling the generation of the SO₄^{-*} radicals only by irradiation with light 742 if desired, the temperature control unit 750 may be used to maintain the temperature of the etching liquid 800 at a temperature at which the generation of SO₄^{-*} radicals due to the temperature does not substantially occur.

When using heating to generate SO₄^{-*} radicals, the temperature control unit 750 may be used to heat the etching liquid 800 to a temperature suitable for the generation of SO₄^{-*} radicals. When the generation of SO₄^{-*} radicals is controlled only by heating, the wavelength of the light 742 may be 310 nm or more (which is 365 nm or less).

In order to facilitate control of the temperature of the etching liquid 800 in the vicinity of the object 450, a temperature control unit 750 (heater, etc.) may be provided on the holding table 711. For example, by heating the object 450 by the temperature control unit 750 (heater) provided on the holding table 711 to the same temperature (etching temperature) as the etching liquid 800, which is heated so as to generate SO₄^{-*} radicals and supplied onto the top surface 455 of the object 450, it is possible to suppress the fluctuation of the amount of the SO₄^{-*} radicals due to the temperature change (temperature decrease) of the etching liquid 800 when it comes into contact with the object 450.

FIGS. 18 (a) and 18 (b) are schematic cross-sectional views of the object 450 (corresponding to a right half from the center of the object 450 illustrated in FIG. 16) illustrating an outline of a PEC etching step. The object 450 and the etching liquid 800 are prepared for performing the PEC etching step. FIG. 18 (a) illustrates the object 450 placed on the holding table 711 of the etching apparatus 700. A mask 451 having an opening is formed in a region (etched region) 452 in which the element separation groove 520 should be formed, on the top surface 455 of the object 450, that is, on the top surface 455 of the element forming layer 430. The mask 451 is formed of a conductive material such as, for example, a metal (eg, titanium (Ti), etc.), and for example, is formed of a non-conductive material such as silicon nitride (SiNₓ), silicon oxide (SiO₂), resist, etc.

FIG. 18 (b) illustrates the object 450 in a situation where PEC etching is applied. The etching liquid 800 is discharged from the discharge port 737 toward the center of the top surface 455 of the rotating object 450 (see also FIG. 16). The discharged etching liquid 800 flows from the center of the object 450 toward the outer peripheral portion, so that the etching liquid 800 is evenly supplied to an entire top surface 455 of the object 450. Then, by irradiating the top surface of the object 450 with light 742 while supplying the etching liquid 800, the group III nitride crystal in the region 452 to be etched is PEC-etched, to form the element separation groove 520.

When the object 450 is, for example, the laminated substrate 410 itself, after the element separation groove 520 is formed, the source electrode 531, the gate electrode 532, the drain electrode 533, and the protective film 540 are formed to form the HEMT 510. In this way, the semiconductor device 500 is manufactured.

Although the aspect in which the element separation groove 520 is formed by PEC etching has been illustrated, the element separation groove 520 is an example of a recess formed by PEC etching (a structure formed by removal by PEC etching). Other recesses such as a source recess for arranging the source electrode 531, a gate recess for arranging the gate electrode 532, a drain recess for arranging the drain electrode 533, included in the semiconductor device 500 may be formed by PEC etching. Regarding the recess such as the gate recess, it is also possible to obtain the recess with less damage due to etching, because it is formed by PEC etching.

Similarly to the example described for the processing apparatus 200 of the first embodiment, the post-treatment may be performed by using the PEC etching apparatus (processing apparatus) 700 and changing the treatment liquid to a post-treatment liquid after PEC etching.

As described above, also in the second embodiment, as in the first embodiment, PEC etching is performed in an aspect in which the top surface 455 of the object 450 is irradiated with light 742, with the top surface 455 of the object 450 immersed in the etching liquid 800 while rotating the object 450. Thereby, similarly to the first embodiment, the distribution of the irradiation intensity (power density) on the top surface 455 can be uniform in the circumferential direction of rotation, and the in-plane uniformity of PEC etching conditions can be improved.

Further, by using the etching apparatus 700 of the present embodiment, PEC etching can be performed by supplying the object 450 with the etching liquid 800 having a constant temperature while rotating the object 450. That is, PEC etching can be performed in such a manner as irradiating the top surface 455 of the object 450 with light 742 while supplying (flowing) the etching liquid 800. At this time, a new (non-deteriorated) etching liquid 800 can be continuously supplied from the tank 720 to the object 450.

Further, even in a case of not submerging the top surface 455 of the object 450 in the etching liquid 800, the etching liquid 800 can be evenly supplied to the entire top surface 455 by making the entire top surface 455 of the object 450 immersed in the etching liquid 800 by rotating the object 450 while supplying the etching liquid 800 to the top surface 455. Thereby, in-plane uniformity of the PEC etching can be improved.

In such an aspect, the thickness of the etching liquid 800 arranged on the top surface 455 is reduced as compared with the aspect in which the top surface 455 of the object 450 is submerged in the etching liquid 800. Therefore, the amount of light 742 absorbed by the etching liquid 800 arranged on the top surface 455 is reduced, and it becomes easy to use the light 742 that has reached the object 450 without being absorbed, for hole generation.

In the second embodiment, it can be said that a relative movement of the etching liquid 800 with respect to the object 450 is more intense than that of the first embodiment, or it can be said that a direction of the movement is different from that of the first embodiment. As described in the first embodiment, it is preferable that various etching methods having different aspects of relative movement of the etching liquid 800 with respect to the object 450 can be appropriately selected and used because the degree of technical freedom can be improved.

In the second embodiment, by performing PEC etching while flowing the etching liquid 800, fresh etching liquid 800 can always be supplied to the top surface 455 of the object 450. Therefore, it is suppressed that the etching does not progress satisfactorily due to the deterioration of the etching liquid 800. That is, the temporal uniformity of the quality of the etching liquid 800 can be improved. Further, in the present embodiment, by performing PEC etching while flowing the etching liquid 800, the temperature rise of the etching liquid, which tends to occur due to light irradiation, is suppressed in the PEC etching of the above aspect in which an etching liquid having no flow is used. That is, since it becomes easy to perform etching at a constant temperature, it is possible to improve the temporal uniformity of etching temperature conditions.

As described above, according to the present embodiment, PEC etching with improved in-plane uniformity and temporal uniformity can be performed. Thereby, as described above, the element separation groove 520 having a feature of high flatness of the inner surface can be formed. Further, since the PEC etching is wet etching, it is possible to form the device separation groove 520 having a feature that the damage to the group III nitride crystal due to etching is hardly generated.

In the aspect in which the generation of SO₄^{-*} radicals is generated by light irradiation, it takes time for the SO₄^{-*} radicals generated near the surface of the etching liquid 800 to diffuse and reach the surface of the object 450. Therefore for example, it is difficult to improve the etching rate. In contrast, by supplying the etching liquid 800 that has been heated in advance to generate SO₄^{-*} radicals, a large amount of SO₄^{-*} radicals can be efficiently supplied to the surface of the object 450. Therefore for example, it is possible to significantly improve the etching rate.

From a viewpoint of increasing the productivity of the semiconductor device 500, the object 450 preferably has a large diameter of, for example, 2 inches or more. Since the PEC etching according to the present embodiment realizes highly uniform etching as described above, it is preferably used as an etching method for such a large-diameter object 450. Accordingly, the holding table 711 is preferably provided so as to hold the object 450 having a diameter of 2 inches or more.

The etching apparatus 700 of the present embodiment may be widely used not only for forming the element separation groove 520 of the semiconductor device 500 but also for PEC etching for forming a structure in a member comprising group III nitride.

### Experimental Example of the Second Embodiment

Next, as an experimental example of the above-described embodiment, explanation will be given for an experimental example in which a groove corresponding to the element separation groove 520 (hereinafter, also referred to as a groove 520) is formed on the laminated substrate 410 by PEC etching. A material used as the HEMT material exemplified above, that is, a material in which a nucleation layer 431 comprising AlN, a channel layer 432 comprising GaN (thickness 1.2 μm), a barrier layer 433 comprising Al_{0.22}Ga_{0.78}N (thickness 24 nm), and a cap layer 434 comprising GaN (thickness 5 nm) are laminated on the SiC substrate 420, was used as the laminated substrate 410.

The mask 451 was formed on the cap layer 434 of the laminated substrate 410, and the groove 520 was formed by emitting the light 742 having a peak wavelength of 260 nm for 120 minutes. The mask 451 was formed of Al/Ti having a thickness of 250 nm. As the etching liquid 800, a mixture of 0.01 M KOH aqueous solution and 0.05 M K₂S₂O₈ aqueous solution was used at a ratio of 1:1.

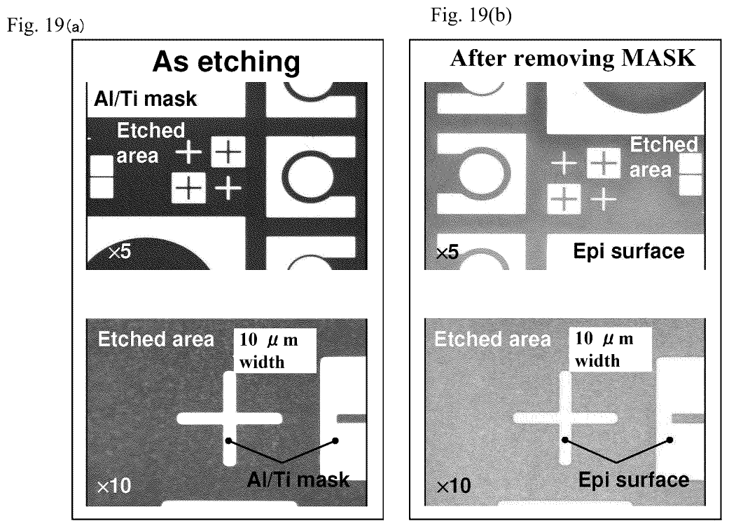

FIGS. 19 (a) and 19 (b) are optical micrographs illustrating the laminated substrate 410 after PEC etching according to the experimental example. FIG. 19 (a) is a photograph before mask removal (As etching), and FIG. 19 (b) is a photograph after mask removal. A mask placement region (Al/Ti mask) in FIG. 19 (a) and a mask-removed region (Epi surface) in FIG. 19 (b) are look brighter than the outside of them, that is, the area where PEC etching is applied (Etched area).

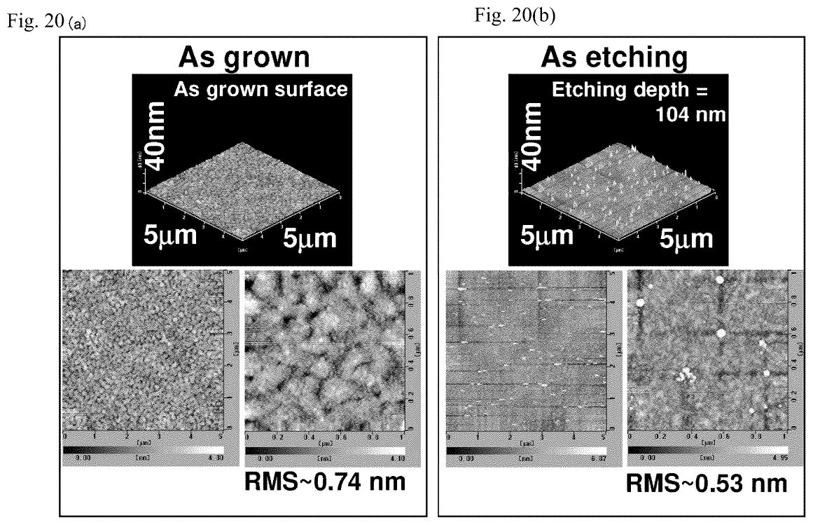

FIGS. 20 (a) and 20 (b) are AFM images of the laminated substrate 410 according to an experimental example. FIG. 20 (a) is an AFM image of the surface of a region (As ground) (hereinafter, also referred to as a non-etched region) where PEC etching is not applied. FIG. 20 (b) is an AFM image of the surface of the PEC-etched region (As etching) (hereinafter, also referred to as an etching region), that is, it is an AFM image of the bottom surface 521 of the groove 520. An etching depth in FIG. 20 (b) is 104 nm.

The RMS surface roughness obtained from the AFM measurement in the 5 μm square region in the non-etched region is 0.74 nm, which is 1 nm or less. RMS surface roughness of the etched region is maintained at 0.53 nm and 1 nm or less in a region excluding a position of a through dislocation (a region excluding a protrusion existing at the position of the through dislocation). Thus, it was found that the PEC etching according to the present embodiment is a method capable of performing etching while maintaining the flatness of the surface, that is, a method capable of forming the groove 520 so that the bottom surface 521 has a high flatness of 1 nm or less as an RMS surface roughness in a region excluding the position of the through dislocation.

The portion of the through dislocation is difficult to be PEC-etched because the life of the hole is short. Therefore, in the etching region, the protrusion is observed at the position of the through dislocation. Through-dislocation density is about 1×10‘ cm-’. However, as described above, such a protruding portion can be lowered by TMAH treatment, etc., after PEC etching.

In this experimental example, the gate electrode, etc., are not formed, that is, the element structure of the HEMT is not formed. However, even when forming the element structure of HEMT, the element separation groove 520 can be formed in the same manner as the groove 520 formed in this experimental example, and therefore as described above, it is possible to obtain the element separation groove 520 with the bottom surface 521 having a high flatness.

### Other Aspects of the Second Embodiment

As described above, the second embodiment and its modified example have been specifically described. However, the present invention is not limited to these, and various changes, improvements, combinations, and the like can be made without departing from the gist thereof.

The etching apparatus 700 is not limited to the one described with reference to FIG. 16, etc., and various modifications as shown below can be made, for example.

The state of accommodating the etching liquid 800 is as follows. It is not limited to the aspect in which the alkaline solution or the acidic solution and the oxidizing agent are mixed in advance and stored in one tank 720, but may be an aspect in which the alkaline solution or the acidic solution and the oxidizing agent are contained in separate containers. In the latter aspect, the alkaline or acidic solution and the oxidizing agent are mixed during use.

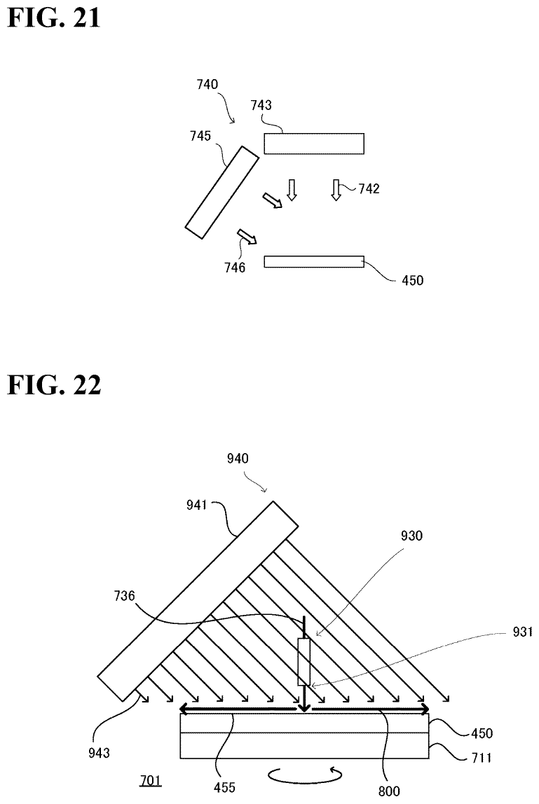

FIG. 21 is a schematic view illustrating the vicinity of the light source of the etching apparatus 700 according to another embodiment in which the light irradiation device 740 is additionally provided to another light source 745. For example, irradiation wavelengths of the light source 743 and the light source 745 may be different, so that the wavelength of the light 742 emitted from the light source 743 of the light irradiation device 740 is 200 nm or more and less than 310 nm, which is a wavelength at which holes and SO₄^{-*} radicals are generated, and the wavelength of the light 746 emitted from the light source 745 of the light irradiation device 740 is 310 nm or more and 365 nm or less, which is a wavelength at which holes are generated but SO₄^{-*} radicals are hardly generated. With such a light source configuration, the generation of holes may be controlled to some extent independently of the generation of SO₄^{-*} radicals. The wavelength condition of the light 742 and the wavelength condition of the light 746 may be exchanged as described above.

Further for example, the irradiation wavelengths of the light source 743 and the light source 745 may be different, so that the wavelength of the light 742 emitted from the light source 743 is 310 nm or more and 365 nm or less, which is a wavelength at which holes are generated but SO₄^{-*} radicals are hardly generated, and the wavelength of the light 746 emitted from the light source 745 is a wavelength in the infrared region (that is, a wavelength to allow the light source 745 function as a temperature control unit 750 for heating the etching liquid 800). With such a light source configuration, the generation of holes may be controlled by light 742, and the generation of SO₄^{-*} radicals may be controlled by heating with light 746.

The light irradiation device 740 is not required to be attached to the arm 735, and may be attached to the outer housing 780 (through the attachment portion 741), for example.

A cooling mechanism for cooling the light irradiation device 740 may be provided. For example, when an air-cooled cooling mechanism is provided, an air inlet/outlet may be provided in a ceiling portion of the outer housing 780, etc.

A reflecting member or a condensing member may be provided so as to guide the light 742 emitted from the light irradiating device 740 to the outside of the object 450 to a predetermined region.

A monitor mechanism (for example, a laser ranging mechanism) for measuring an etching amount (etching depth) may be provided.

A cleaning mechanism may be provided to clean the object 450 after the PEC etching has been performed. Also, a drying mechanism for drying the object 450 may be provided.

An exhaust mechanism for exhausting the inside of the etching apparatus 700 may be provided.

A transport mechanism may be provided for transporting the object 450 onto the holding table 711 and transporting the object 450 from the holding table 711.

### Third Embodiment

Next, a third embodiment will be described. FIG. 22 is a schematic view illustrating the vicinity of the object 450 of the PEC etching apparatus 701 according to the third embodiment. In the third embodiment, explanation will be given for the PEC etching apparatus 701 in an aspect in which the configurations of the supply unit 730 and the light irradiation device 740 in the PEC etching apparatus 700 of the second embodiment are changed to the configurations of a supply unit 930 and a light irradiation device 940. The configurations of the other parts may be the same as those of the second embodiment. In the second embodiment, the PEC etching apparatus 700 in the aspect in which the light irradiation device 740 is attached to the supply unit 730 is exemplified. In the third embodiment, the supply unit 930 and the light irradiation device 940 are provided so as to be arranged independently of each other.

The light irradiation device 940 has a light source 941 and the light source 941 emits light 943. The light source 941 is preferably a light source that emits parallel light. Thereby, an incident direction of the light 943 incident on the top surface 455 of the object 450 can be aligned on the top surface 455. The light source that emits parallel light may be, for example, a light source that emits parallel light from the light source, and, for example, may be configured to convert the light emitted from the light generation source into parallel light by an optical system such as a lens or a mirror.

The supply unit 930 has a discharge port 931 for discharging the etching liquid 800. The configuration on an upstream side from the pipe 736 that supplies the etching liquid 800 to the discharge port 931 may be the same as that of the supply unit 730 of the second embodiment. The discharge port 931 may be arranged at an arbitrary height independent of the light irradiation device 940, for example, at a height close to the top surface 455 so as to be preferable for discharging the etching liquid 800.

The second embodiment shows the configuration of the PEC etching apparatus 700, in which shadows of the members constituting the PEC etching apparatus 700 (for example, the members constituting the discharge port 737 of the etching liquid 800 in the supply unit 730, or, for example, a pipe 736) of the supply unit 730, due to the light 742 emitted from the light irradiation device 740, are not reflected on the top surface 455 of the object 450 (see FIG. 16). Specifically, for example such shadows were suppressed by arranging the discharge port 737 above the height of the light irradiation device 740, and by arranging the discharge port 737 at a position that does not overlap with the light irradiation device 740 in a plan view, for example.

The third embodiment shows the configuration of the PEC etching apparatus 701, in which shadows of the members constituting the PEC etching apparatus 701 (for example, the members constituting the discharge port 931 of the etching liquid 800 in the supply unit 930, or, for example, a pipe 736 of the supply unit 930) due to the light 943 emitted from the light irradiation device 940 may be reflected on the top surface 455 of the object 450. Specifically for example, such shadows may be generated by arranging the discharge port 931 lower than the light irradiation device 940, or by arranging the discharge port 931 at a position overlapping with the light irradiation device 940 in a plan view.

FIG. 22 illustrates a situation in which the shadow of the discharge port 931 (shadow of the member constituting the discharge port 931) due to the light 943 (in the PEC etching step) is reflected on the top surface 455 of the object 450. The light irradiation device 940 (light source 941) obliquely irradiates the top surface 455 with light 943. “Irradiating light 943 obliquely to the top surface 455” means that an angle formed by a traveling direction of the light 943 with respect to a normal direction of the top surface 455 is more than 0° and less than 90°, for example, 5° or more and 85°. For example, in order to increase an irradiation intensity (power density) in an irradiation cross section, the angle may be brought closer to 0° (that is, closer to vertical irradiation). Further for example, when it is difficult to cast the shadow of the discharge port 931, etc., on the top surface 455, the angle may be brought closer to 900 (that is, closer to horizontal irradiation).

In the example illustrated in FIG. 22, the discharge port 931 is arranged on the center of rotation of the object 450, but since the light 943 is emitted obliquely, the shadow of the discharge port 931 is not reflected on the center of rotation on the top surface 455, but is reflected on the outer peripheral side of the center. Therefore, it is possible to prevent a situation that the shadow continues to fall on the center of rotation. At the same time, since the region where the shadow is formed on the top surface 455 is arranged on the outer peripheral side, the region moves in the circumferential direction with rotation. The deviation of the distribution of irradiation intensity due to the shadow on the top surface 455 can be uniform in a circumferential direction.

Since the discharge port 931 is closest to the top surface 455 of the supply unit 930, it is a portion where the shadow is easily formed. Therefore, a device configuration in which the shadow of the discharge port 931 may be reflected on the top surface 455, is preferable in order to increase the degree of freedom in arranging the members constituting the supply unit 930 (or, the degree of freedom in arranging the members constituting the light irradiation device 940). Even when other members constituting the PEC etching apparatus 701 cast a shadow on the top surface 455, the same idea can be applied. By rotating the object 450 and supplying the etching liquid 800 to the top surface 455 of the object 450 while emitting the light 943 obliquely, PEC etching can be performed by the PEC etching apparatus 701 of the present embodiment, with a shadow influence reduced, the shadow being created, for example, by the supply unit 930.

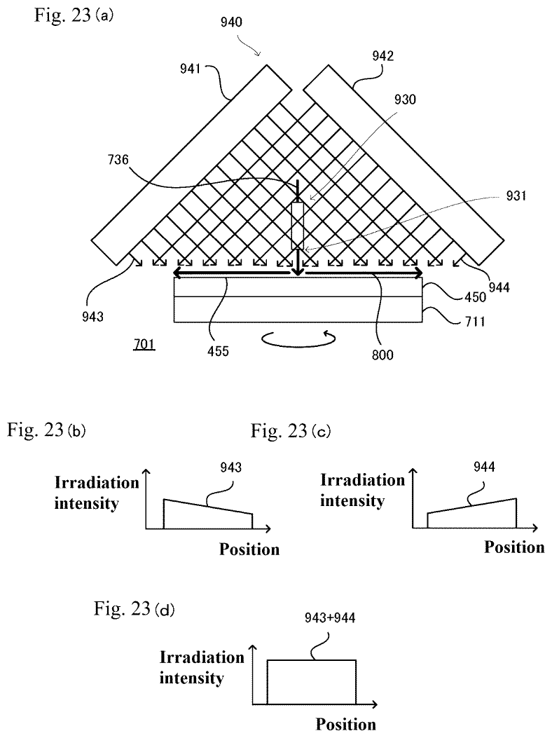

Due to the oblique irradiation, the distance from the light source 941 to the top surface 455 of the object 450 changes depending on a position on the top surface 455. Due to this, the irradiation intensity is sometimes not constant within the top surface 455. For example, as illustrated in FIG. 23 (b), the distribution of irradiation intensity may occur in such manner that the irradiation intensity is high on the side closer to the light source 941 and the irradiation intensity is low on the side far from the light source 941. By emitting the light 943 while rotating the object 450, the deviation of the distribution of irradiation intensity due to such oblique irradiation can be uniform in the circumferential direction.

The effect of making the deviation in the distribution of irradiation intensity due to the oblique irradiation uniform in the circumferential direction by rotation, can be obtained regardless of presence or absence of the shadow on the top surface 455. For example, as another aspect of the second embodiment, the same effect can be obtained regarding the light source 745 that performs oblique irradiation, with the apparatus configuration described with reference to FIG. 21.

Next, a modified example of the third embodiment will be described. FIG. 23 is a schematic view illustrating the vicinity of the object 450 of the PEC etching apparatus 701 according to this modified example. The modified example shows an aspect in which the light irradiation device 940 has a plurality of light sources, for example, two light sources of a light source 941 and a light source 942. The light irradiation device 940 may include three or more light sources, if necessary. Since the light source 941 is arranged so as to perform oblique irradiation, it is easy to spatially add another light source 942, etc., to the light irradiation device 940. The plurality of light sources are arranged side by side in a circumferential direction, for example, around the center of rotation.

The light source 942 emits the light 944 that irradiates the top surface 455 from a direction different from the light 943 emitted from the light source 941 (in the PEC etching step). That is, the light irradiation device 940 irradiates the top surface 455 with light in which light 943 and light 944 are superimposed (combined) (the light irradiation device 940 irradiates the top surface 455 with light including at least light 943 and light 944). By superimposing the light 943 and the light 944, it becomes easy to increase the irradiation intensity on the top surface 455 and adjust the distribution of irradiation intensity.

The light source 942 irradiates the top surface 455 with light 944 from the side facing the light source 941 with the center of rotation of the object 450 interposed therebetween. As described above, on the top surface 455, the distribution of irradiation intensity may occur in such a manner that the irradiation intensity is high on the side closer to the light source and the irradiation intensity is low on the side far from the light source. The schematic distribution of irradiation intensity of the light 943 emitted from the light source 941 and the light 944 of the light source 942 are illustrated in FIGS. 23 (b) and 23 (c), respectively. Since the light source 941 and the light source 942 are arranged to face each other, the side closer to the light source and the side far from the light source on the top surface 455 are opposite to each other. Therefore, as illustrated in FIG. 23 (d), by superimposing the light 943 and the light 944, the top surface 455 can be irradiated with light so that the strength of each other's irradiation intensity is canceled out, that is, so that the distribution of irradiation intensity with improved in-plane uniformity can be obtained.

Thus, according to the light irradiation device 940 according to this modified example, irradiation with light 943 and light 944 is enabled so that the uniformity of the distribution of irradiation intensity is improved on the top surface 455 when irradiated with both light 943 and light 944, compared with the distribution of irradiation intensity on the top surface 455 when irradiated with only one of light 943 and light 944.

Further, in this modified example, light irradiation is performed by the light irradiation device 940 so that the light 944 of the light source 942 hits on the shadow of the discharge port 931, the shadow being made due to the light 943 of the light source 941, and at the same time, the light 943 of the light source 941 hits on the shadow of the discharge port 931, the shadow being made due to the light 944 of the light source 942. Thereby, an influence of the decrease in irradiation intensity due to the shadow on the top surface 455 can be suppressed.

If necessary, the plurality of light sources included in the light irradiation device 940 may include those that perform vertical irradiation. With the light of the light source that performs vertical irradiation, by irradiating the shadow with the light of another light source that performs oblique irradiation (that is, on the center of rotation), it is possible to suppress that the light does not hit on the center of rotation., even if the shadow of the discharge port 931 etc., casts on the center of rotation.

### Other Embodiments

As described above, the embodiments and modified examples of the present invention have been specifically described. However, the present invention is not limited to the above-described embodiments and modified examples, and various changes, improvements, combinations, etc., can be made without departing from the gist thereof.

For example, configurations such as the supply unit 930 and the light irradiation device 940 in the third embodiment may be applied to the PEC etching apparatus of the first embodiment.

Further for example, in the PEC etching apparatus as in the first embodiment, PEC etching may be performed in a manner as in the second and third embodiments in which the etching liquid is spread by rotation (see FIG. 3 (a)).

<Preferable Aspects of the Present Invention>

Hereinafter, preferable aspects of the present invention will be supplementarily described.

### (Supplementary Description 1)

There is provided a structure manufacturing method, including:
containing an object to be treated having a region to be etched comprising group III nitride in a container while being immersed in an etching liquid containing peroxodisulfate ions; and
etching the region to be etched by generating sulfate ion radicals by heating the etching liquid to a predetermined temperature and generating holes by irradiating the region to be etched with light.

### (Supplementary Description 2)

There is provided the structure manufacturing method, wherein the predetermined temperature is 45° C. or higher (preferably 50° C. or higher, more preferably 60° C. or higher, still more preferably 70° C. or higher).

### (Supplementary Description 3)

The structure manufacturing method according to supplementary description 1 or 2, wherein the etching liquid is heated to a temperature lower than the predetermined temperature and then heated to the predetermined temperature.

### (Supplementary Description 4)

The structure manufacturing method according to any one of supplementary descriptions 1 to 3, wherein the predetermined temperature is less than 100° C. (preferably 95° C. or lower).

### (Supplementary Description 5)

The structure manufacturing method according to any one of supplementary descriptions 1 to 4, wherein the etching liquid is prepared by dissolving (at least) a salt of peroxodisulfate ion in water so that a concentration at the time of preparation, which is a concentration of peroxodisulfate ion at the time when the etching liquid is prepared, becomes a predetermined concentration.

### (Supplementary Description 6)

The structure manufacturing method according to supplementary description 5, wherein the concentration at the time of preparation is set to a (high) concentration such that an etching rate for etching the region to be etched in etching performed using the etching liquid having the concentration at the time of preparation and heated to 50° C. or higher, is higher (high etching rate) than an etching rate in etching performed using the etching liquid having the concentration at the time of preparation and heated to 30° C.,

### (Supplementary Description 7)

There is provided the structure manufacturing method according to supplementary description 5 or 6, wherein the concentration at the time of preparation is set to a (high) concentration such that an etching rate for etching the region to be etched in etching performed using the etching liquid having the concentration at the time of preparation and heated to 50° C. or higher, is 6 nm/min or more (preferably 10 nm/min or more, more preferably 15 nm/min or more, still more preferably 20 nm/min or more).

### (Supplementary Description 8)

There is provided the structure manufacturing method according to any one of supplementary descriptions 5 to 7, wherein the concentration at the time of preparation is 0.075 mol/L or more (preferably 0.1 mol/L or more, more preferably 0.15 mol/L or more, still more preferably 0.2 mol/L or more, still more preferably 0.25 mol/L or more).

### (Supplementary Description 9)

There is provided the structure manufacturing method according to any one of supplementary descriptions 5 to 8, wherein the concentration at the time of preparation is set to a (high) concentration such that an etching rate for etching the region to be etched in etching performed using the etching liquid having the concentration at the time of preparation and heated to 80° C. or higher, is 1.2 times or less the etching rate in etching performed using the etching liquid having the concentration at the time of preparation and heated to 70° C.

### (Supplementary Description 10)

There is provided the structure manufacturing method according to any one of supplementary descriptions 5 to 9, wherein the salt is not precipitated (not left undissolved) in the etching liquid heated to the predetermined temperature.

### (Supplementary Description 11)

There is provided the structure manufacturing method according to any one of supplementary descriptions 5 to 9, wherein the salt is precipitated (remains undissolved) in the etching liquid heated to the predetermined temperature.

### (Supplementary Description 12)

There is provided the structure manufacturing method according to any one of supplementary descriptions 5 to 11, wherein a salt containing no alkali metal element is used as the salt.

### (Supplementary Description 13)

There is provided the structure manufacturing method according to any one of supplementary descriptions 5 to 12, wherein ammonium peroxodisulfate is used as the salt.

### (Supplementary Description 14)

There is provided the structure manufacturing method according to any one of supplementary descriptions 1 to 13, wherein the etching rate for etching the region to be etched, is 6 nm/min or more (preferably 10 nm/min or more, more preferably 15 nm/min or more, still more preferably 20 nm/min or more, still more preferably 25 nm/min or more).

### (Supplementary Description 15)

There is provided the structure manufacturing method according to any one of supplementary descriptions 1 to 14, wherein the etching is performed so that an etching rate due to generation of sulfate ion radicals by heating the etching liquid, is larger than an etching rate due to generation of sulfate ion radicals by irradiation with light having a wavelength component of a wavelength (200 nm or more) and less than 310 nm contained in the light, in the etching rates for etching the region to be etched.

### (Supplementary Description 16)

There is provided the structure manufacturing method according to any one of supplementary descriptions 1 to 15, wherein sulfate ion radicals are generated at a rate of 1.6×10⁻⁴ (mol/L)/min or more.

### (Supplementary Description 17)

There is provided the structure manufacturing method according to any one of supplementary descriptions 1 to 16, wherein an irradiation intensity of the light for irradiating the etching liquid at a predetermined wavelength included in a wavelength (200 nm or more) of less than 310 nm, is 3 mW/cm² or less.

### (Supplementary Description 18)

There is provided the structure manufacturing method according to any one of supplementary descriptions 1 to 17, wherein the etching liquid is acidic at the time when etching of the region to be etched is started.

### (Supplementary Description 19)

There is provided the structure manufacturing method according to any one of supplementary descriptions 1 to 17, wherein the etching liquid is alkaline at the time when etching of the region to be etched is started. Preferably, the etching liquid remains alkaline (more preferably, pH is 9 or more) during a period of etching the region to be etched.

### (Supplementary Description 20)

There is provided the structure manufacturing method according to supplementary description 19, wherein the etching liquid is a mixed solution in which an aqueous solution of a salt of (at least) a salt of peroxodisulfate ion and an alkaline aqueous solution are mixed.

### (Supplementary Description 21)

There is provide the structure manufacturing method according to supplementary description 19 or 20, wherein a pH decrease width (difference between a maximum pH and a minimum pH) of the etching liquid is 5 or less (preferably 4 or less, more preferably 3 or less) during the period of etching the region to be etched. An alkaline aqueous solution may be added to the etching liquid during the period of etching the region to be etched in order to suppress a decrease of pH. In order to increase the pH, the pH of the etching liquid at the time of starting etching of the region to be etched may be preferably 11 or more (more preferably 12 or more, still more preferably 13 or more).

### (Supplementary Description 22)

There is provide the structure manufacturing method according to any one of supplementary descriptions 1 to 21, wherein a temperature of the etching liquid is measured by a thermometer arranged at a position where a shadow of the light is not reflected on a surface of the object to be treated.

### (Supplementary Description 23)

There is provided the structure manufacturing method according to any one of supplementary descriptions 1 to 22, wherein the etching liquid is heated while stirring the etching liquid.

### (Supplementary Description 24)

There is provided the structure manufacturing method according to any one of supplementary descriptions 1 to 23, wherein the etching is performed in a state where the object to be treated is fixed to a container for containing the object to be treated.

### (Supplementary Description 25)

There is provided the structure manufacturing method according to any one of supplementary descriptions 1 to 24, wherein after etching the region to be etched, post-treatment is performed to the object to be treated (and cooling the object to be treated) with a post-treatment liquid having a temperature lower than the predetermined temperature.

### (Supplementary Description 26)

There is provided the structure manufacturing method according to any one of supplementary descriptions 1 to 25, wherein the object to be treated has an etching target having the region to be etched, and a conductive member of the etching target, which is provided so as to be in contact with at least a part of a surface of a conductive region electrically connected to the region to be etched, and the etching is performed in a state where the conductive member is in contact with the etching liquid.

### (Supplementary Description 27)

There is provided the structure manufacturing method according to any one of supplementary descriptions 1 to 26, wherein a surface of the object to be treated opposite to a surface irradiated with the light is a conductive surface electrically connected to the region to be etched, and the etching is performed in a state where the region to be etched and the opposite surface are in contact with the etching liquid.

### (Supplementary Description 28)

There is provided the structure manufacturing method according to any one of supplementary descriptions 1 to 27, wherein the object to be treated has a first layer, a second layer arranged on the first layer and constituting the region to be etched, and a third layer arranged on the second layer, and
by removing the second layer by the etching, the first layer and the third layer are separated.

### (Supplementary Description 29)

There is provided the structure manufacturing method according to supplementary description 28, wherein the third layer comprises a group III nitride that transmits the light by having a band gap wider than that of the group III nitride constituting the second layer, and the light is transmitted through the third layer and emitted to the second layer, and the second layer is selectively etched with respect to the third layer in a state where an end face of the second layer is in contact with the etching liquid.

### (Supplementary Description 30)

There is provided a structure manufacturing apparatus, including:
a container that houses an object to be treated having a region to be etched comprising group III nitride in a state of being immersed in an etching liquid containing peroxodisulfate ions; (at least one) heater that heats the etching liquid;
a light irradiation device that irradiates the region to be etched with light; and
a control device that controls the heater and the light irradiation device, so that the region to be etched is etched by generating sulfate ion radicals by heating the etching liquid to a predetermined temperature and generating holes by irradiating the region to be etched with light.

### (Supplementary Description 31)

There is provided the structure manufacturing apparatus according to supplementary description 30, including a first heater that heats the etching liquid before it is injected (contained) into the container.

### (Supplementary Description 32)

There is provided the structure manufacturing apparatus according to supplementary description 31, including an etching liquid injection device that injects the etching liquid into the container, wherein the first heater is provided in the etching liquid injection device.

### (Supplementary Description 33)

There is provided the structure manufacturing apparatus according to any one of supplementary descriptions 30 to 32, wherein the heater has a second heater that heats the etching liquid after being injected (contained) in the container.

### (Supplementary Description 34)

There is provided the structure manufacturing apparatus according to supplementary description 33, wherein the second heater is provided in the container.

### (Supplementary Description 35)

There is provided the structure manufacturing apparatus according to supplementary description 34, wherein the second heater is a lamp that irradiates the etching liquid with infrared light.

### (Supplementary Description 36)

There is provided the structure manufacturing apparatus according to any one of supplementary descriptions 30 to 35, including a thermometer that measures a temperature of the etching liquid, wherein the thermometer is arranged at a position where a shadow of the thermometer due to the light is not reflected in the region to be etched. The heater is preferably controlled based on the temperature of the etching liquid measured by the thermometer.

### (Supplementary Description 37)

There is provided the structure manufacturing apparatus according to any one of supplementary descriptions 30 to 36, including a stirring device that stirs the etching liquid.

### (Supplementary Description 38)

There is provided the structure manufacturing apparatus according to supplementary description 37, wherein the stirring device (rotating device) stirs the etching liquid by moving the container.

### (Supplementary Description 39)

There is provided the structure manufacturing apparatus according to supplementary description 38, wherein a convex portion (fin) for stirring the etching liquid is provided on a side surface or a bottom surface of the container.

### (Supplementary Description 40)

There is provided the structure manufacturing apparatus according to any one of supplementary descriptions 37 to 39, wherein the stirring device (stirrer) stirs the etching liquid by moving a stirring member in the etching liquid.

### (Supplementary Description 41)

There is provided the structure manufacturing apparatus according to any one of supplementary descriptions 30 to 40, including a fixing device that fixes the object to be treated to the container.

### (Supplementary Description 42)

There is provided the structure manufacturing apparatus according to supplementary description 41, wherein the fixing device fixes the object to be treated so that a surface of the object to be treated opposite to the surface irradiated with the light is arranged away from the bottom surface in the container.

### (Supplementary Description 43)

There is provided the structure manufacturing apparatus according to any one of supplementary descriptions 30 to 42, wherein the container is held rotatably, and the etching liquid can be discharged from the container by rotating the container and scattering the etching liquid toward an outer peripheral side.

### (Supplementary Description 44)

There is provided the structure manufacturing apparatus according to any one of supplementary descriptions 30 to 43, including a post-treatment liquid injection device that injects a post-treatment liquid having a temperature lower than the predetermined temperature into the container.

### (Supplementary Description 45)

There is provided the structure manufacturing apparatus according to any one of supplementary descriptions 30 to 44, wherein the light irradiation device has, as a light source for emitting the light, a semiconductor light irradiation device comprising a semiconductor material having a wavelength corresponding to a band gap of 310 nm or more. The light irradiation device is an example of a light irradiation device configured to emit light in which a short wavelength component having a wavelength of less than 310 nm is attenuated.

### (Supplementary Description 46)

There is provided the structure manufacturing apparatus according to any one of supplementary descriptions 30 to 45, wherein the light irradiation device includes a filter that attenuates a wavelength component in a wavelength range of less than 310 nm. The light irradiation device is another example of a light irradiation device configured to emit light in which a short wavelength component having a wavelength of less than 310 nm is attenuated.

### (Supplementary Description 47)

There is provided a structure manufacturing apparatus, including:
a container for an object to be treated and an etching liquid;
a heater that heats the etching liquid;
a light irradiation device that irradiates the object to be treated with light;
a thermometer that measures a temperature of the etching liquid by arranging it at a position where a shadow of the light does not appear on a surface of the object to be treated; and
a control device that controls the heater and the light irradiation device, and
configured to perform photoelectrochemical etching to the object to be treated.

### (Supplementary Description 48)

There is provided a structure manufacturing apparatus, including
a container that houses an object to be treated and an etching liquid;
a heater that heats the etching liquid;
a light irradiation device that irradiates the object to be treated with light;
a fixing device that fixes the object to be treated to the container; and
a control device that controls the heater and the light irradiation device,
and configured to perform photoelectrochemical etching to the object to be treated (with the generation of bubbles during etching).

### (Supplementary Description 49)

There is provided a group III nitride semiconductor device, including:
an element forming layer comprising a group III nitride crystal and formed with a first semiconductor element and a second semiconductor element;
an element separation groove provided in the element forming layer and separating between the first semiconductor element and the second semiconductor element,
wherein a root mean square surface roughness in a region of a bottom surface of the element separation groove excluding a position of a through dislocation of the group III nitride crystal in a region of 5 μm square observed by an atomic force microscope, is 1 nm or less.

### (Supplementary Description 50)

There is provided the group III nitride semiconductor device according to supplementary description 49, including a protrusion at a position of the through dislocation in the observed 5 μm square region.

### (Supplementary Description 51)

There is provided the group III nitride semiconductor device according to supplementary description 49 or 50, wherein a band edge peak intensity of a PL emission spectrum on a bottom surface of the element separation groove has an intensity of 90% or more with respect to a band edge peak intensity of the PL emission spectrum on a top surface of the element forming layer.

### (Supplementary Description 52)

There is provided the group III nitride semiconductor device according to any one of supplementary descriptions 49 to 51, wherein the first semiconductor element and the second semiconductor element are high electron mobility transistors, the element forming layer has a channel layer and a barrier layer formed above the channel layer, and the bottom surface of the element separation groove is arranged at a position deeper than the top surface of the channel layer.

### (Supplementary Description 53)

There is provided an etching apparatus, including:
a holding unit that holds an etching target at least whose top surface comprises group III nitride crystal;
a container (tank) that stores an alkaline or acidic etching liquid containing oxygen used for producing an oxide of a group III element contained in the group III nitride crystal and further containing an oxidizing agent for receiving electrons;
a supply unit that supplies the etching liquid onto the top surface of the etching target; and
a light emitting unit (light irradiation device) that emits light having a wavelength of 365 nm or less onto the top surface of the etching target, and
configured to apply photoelectrochemical etching to the group III nitride crystal.

### (Supplementary Description 54)

There is provided an etching apparatus according to supplementary description 53,
wherein the supply unit has a discharge port for discharging the etching liquid toward the top surface of the etching target, and
the discharge port and the light emitting unit are arranged at positions that overlap with the etching target, in a plan view when the etching target is held by the holding unit and the photoelectrochemical etching is performed.

### (Supplementary Description 55)

There is provided the etching apparatus according to supplementary description 54, wherein the supply unit has a pipe for transporting the etching liquid through a region overlapping with the etching target in the plan view, and the pipe is arranged at a position where a shadow of the pipe due to the light emitted from the light emitting unit is not reflected on the top surface of the etching target.

### (Supplementary Description 56)

There is provided the etching apparatus according to supplementary description 55, wherein the pipe is arranged so as to pass above the light emitting unit.

### (Supplementary Description 57)

There is provided the etching apparatus according to supplementary description 55 or 56, wherein the pipe is arranged at a position that does not overlap with the light emitting unit in the plan view.

### (Supplementary Description 58)

There is provided the etching apparatus according to any one of supplementary descriptions 54 to 57, wherein the light emitting unit is arranged at a position that does not interfere with a discharging operation of the etching liquid from the discharge port.

### (Supplementary Description 59)

There is provided the etching apparatus according to any one of supplementary descriptions 54 to 58, wherein the light emitting unit is arranged up to a position overhanging an outside of the etching target in the plan view.

### (Supplementary Description 60)

There is provided the etching apparatus according to any one of supplementary descriptions 54 to 59, wherein the holding unit rotatably holds the etching target.

### (Supplementary Description 61)

There is provided the etching apparatus according to supplementary description 60, wherein the discharge port discharges the etching liquid toward a center of rotation of the etching target.

### (Supplementary Description 62)

There is provided the etching apparatus according to supplementary description 60 or 61, wherein the light emitting unit is arranged in a part of a circumferential direction of the etching target in the plan view.

### (Supplementary Description 63)

There is provided the etching apparatus according to any one of supplementary descriptions 53 to 62, including a temperature control unit that controls a temperature of the etching liquid.

### (Supplementary Description 64)

There is provided the etching apparatus according to supplementary description 63, wherein the temperature control unit adjusts the temperature of the etching liquid stored in the container.

### (Supplementary Description 65)

There is provided the etching apparatus according to supplementary description 63 or 64, wherein the temperature control unit is provided to the holding unit.

### (Supplementary Description 66)

There is provided the etching apparatus according to any one of supplementary description 63 to 65, wherein the temperature control unit is provided as a light emitting unit that emits light having a wavelength in an infrared region.

### (Supplementary Description 67)

There is provided the etching apparatus according to any one of supplementary description 53 to 66, wherein the holding unit is provided so as to hold the etching target having a diameter of 2 inches or more.

### (Supplementary Description 68)

There is provided a structure manufacturing method, including:
preparing an alkaline or acidic etching liquid containing a peroxodisulfate ion as an oxidizing agent that receives electrons and an etching target whose top surface comprises group III nitride crystal; and
irradiating the top surface of the etching target with light, with the top surface of the etching target immersed in the etching liquid heated so as to generate sulfate ion radicals.

### (Supplementary Description 69)

There is provided the structure manufacturing method according to supplementary description 68, wherein in the irradiation of the light, the light is emitted to the top surface of the etching target while supplying (flowing) the etching liquid onto the top surface of the etching target.

### (Supplementary Description 70)

There is provided the structure manufacturing method according to supplementary description 68 or 69, wherein in the irradiation of the light, by rotating the etching target while supplying the etching liquid onto the top surface of the etching target without submerging the top surface of the etching target in the etching liquid, (by flowing the etching liquid from a center side of rotation to an outer peripheral side on the top surface of the etching target), an entire top surface of the etching target is immersed in the etching liquid.

### (Supplementary Description 71)

There is provided the structure manufacturing method according to any one of supplementary descriptions 68 to 70, wherein in the irradiation of the light, the light is obliquely emitted to the top surface of the etching target.

### (Supplementary Description 72)

There is provided the structure manufacturing method according to any one of supplementary descriptions 68 to 71, wherein in the irradiation of the light, the light is emitted so that a shadow of a member due to the light, the member constituting a structure manufacturing apparatus used in the structure manufacturing method (for example, the member constituting a discharge port of the etching liquid), does not appear on the top surface of the etching target.

### (Supplementary Description 73)

There is provided the structure manufacturing method according to any one of supplementary descriptions 68 to 71, wherein in the irradiation of the light, the light is emitted so that a shadow of a member due to the light, the member constituting a structure manufacturing apparatus used in the structure manufacturing method (for example, the member constituting a discharge port of the etching liquid), is not reflected in a center of rotation on a top surface of the etching target, but is reflected on an outer peripheral side of the center.

### (Supplementary Description 74)

There is provided the structure manufacturing method according to any one of supplementary descriptions 68 to 70, wherein in the irradiation of the light, light containing at least a first light and a second light emitted from a direction different from the first light, is emitted as the light.

### (Supplementary Description 75)

There is provided the structure manufacturing method according to supplementary description 74, wherein in the irradiation of the light, the first light and the second light are emitted, so as to improve uniformity of a distribution of irradiation intensity (power density) on a top surface of the etching target when both the first light and the second light are irradiated, compared with a distribution of irradiation intensity (power density) on the top surface of the etching target when only one of the first light and the second light is irradiated.

### (Supplementary Description 76)

There is provided the structure manufacturing method according to supplementary description 74 or 75, wherein in the irradiation of the light, the light is emitted so that a shadow of a member due to the first light, the member constituting a structure manufacturing apparatus used in the structure manufacturing method (for example, the member constituting a discharge port of the etching liquid), is reflected on the top surface of the etching target, and the second light hits on the shadow. The shadow may appear on the center of rotation.

### (Supplementary Description 77)

There is provided the structure manufacturing method according to supplementary description 68 or 69, wherein in the irradiation of the light, by containing the etching target and the etching liquid in the container so that the top surface of the etching target is submerged in the etching liquid, the entire top surface of the etching target is immersed in the etching liquid, and by rotating the container, the etching liquid is rotated together with the etching target.

### (Supplementary Description 78)

There is provided a structure manufacturing apparatus, including:
a holding unit that rotatably holds (configured to hold) an etching target at least whose top surface comprises group III nitride crystal;
a supply unit (configured to supply) an alkaline or acidic etching liquid containing peroxodisulfate ions as an oxidizing agent that receives electrons onto the top surface of the etching target;
a heater (configured to heat) the etching liquid;
a light irradiation device that irradiates (configured to irradiate) the top surface of the etching target with light; and
a control device that controls (configured to control) the holding unit, the supply unit, the heater, and the light irradiation device, so that a top surface of the etching target is irradiated with the light while the top surface of the etching target is immersed in the etching liquid heated so as to generate sulfate ion radicals, while rotating the etching target.

### (Supplementary Description 79)

There is provided the structure manufacturing apparatus according to supplementary description 78, wherein the control device controls the supply unit and the light irradiation device so that the top surface of the etching target is irradiated with the light while supplying the etching liquid onto the top surface of the etching target.

### (Supplementary Description 80)

There is provided the structure manufacturing apparatus according to supplementary description 78 or 79,
wherein the holding unit holds (is configured to hold) the etching target so that the top surface of the etching target is not submerged in the etching liquid, and
the control device controls (is configured to control) the holding unit and the supply unit, so that an entire top surface of the etching target is immersed in the etching liquid, by rotating the etching target (by flowing the etching liquid from a center side to an outer peripheral side of rotation on the top surface of the etching target), while supplying the etching liquid onto the top surface of the etching target.

### (Supplementary Description 81)

There is provided the structure manufacturing apparatus according to any one of supplementary description 78 to 80, wherein the light irradiation device obliquely emits (is configured to emit) the light to the top surface of the etching target.

### (Supplementary Description 82)

There is provided the structure manufacturing apparatus according to any one of supplementary description 78 to 81, wherein the light irradiation device, the holding unit, and the member are arranged (configured), so that a shadow of a member due to the light, the member constituting a structure manufacturing apparatus used in the structure manufacturing method (for example, the member constituting a discharge port of the etching liquid), is not reflected on the top surface of the etching target.

### (Supplementary Description 83)

There is provided the structure manufacturing apparatus according to any one of supplementary description 78 to 81, wherein the light irradiation device, the holding unit, and the member are arranged (configured), so that a shadow of a member due to the light, the member constituting a structure manufacturing apparatus used in the structure manufacturing method (for example, the member constituting a discharge port of the etching liquid), is not reflected in a center of rotation on the top surface of the etching target, but is reflected on an outer peripheral side of the center.

### (Supplementary Description 84)

There is provided the structure manufacturing apparatus according to any one of supplementary description 78 to 80, wherein the light irradiation device emits (is configured to emit) light including at least a first light and a second light emitted from a direction different from the first light, as the light.

### (Supplementary Description 85)

There is provided the structure manufacturing apparatus according to supplementary description 84, wherein the light irradiation device emits (is configured to emit) the first light and the second light, to improve uniformity of a distribution of irradiation intensity (power density) on a top surface of the etching target when both the first light and the second light are irradiated, compared with a distribution of irradiation intensity (power density) on the top surface of the etching target when only one of the first light and the second light is irradiated.

### (Supplementary Description 86)

There is provided the structure manufacturing apparatus according to supplementary description 84 or 85, wherein the light irradiation device emits (configured to emit) the light, so that a shadow of a member due to the light, the member constituting a structure manufacturing apparatus used in the structure manufacturing method (for example, the member constituting a discharge port of the etching liquid), is reflected on the top surface of the etching target and the second light hits on the shadow.

### (Supplementary Description 87)

There is provided the structure manufacturing apparatus according to supplementary description 78 or 79, wherein the holding unit includes a container configured such that an entire top surface of the etching target is immersed in the etching liquid by containing the etching target and the etching liquid so that the top surface of the etching object is submerged in the etching liquid, and by rotating the container, the etching liquid is rotated (configured so as to be rotated) together with the etching target.

### DESCRIPTION OF SIGNS AND NUMERALS

10 . . . Etching target (wafer), 20 . . . Region to be etched, 30 . . . Cathode pad, 50 . . . Mask, 100 . . . Object to be treated, 101 . . . Top surface, 200 . . . Structure manufacturing apparatus (treatment device, PEC-etching apparatus), 210 . . . container, 220 . . . light irradiation device, 221 . . . Light source, 222 . . . Filter, 225 . . . Light, 230 . . . Heater, 230A . . . Pre-injection heater, 230B . . . Post-injection heater, 231 . . . Container heater, 232 . . . Lamp heater, 233 . . . Injection device heater, 234 . . . Injection device spare heater, 240 . . . Injection device, 241 . . . Etching liquid injection device, 242 . . . Post-treatment liquid injection device, 243 . . . Discharging unit, 244 . . . Supply unit, 245 . . . Tank, 246 . . . Pipe, 250 . . . Thermometer, 260 . . . Stirrer, 261 . . . Rotating device, 262 . . . Fins, 263 . . . Stirrer, 264 . . . Holding unit, 270 . . . Fixing device, 280 . . . Control device, 300 . . . Treatment liquid, 310 . . . Etching liquid, 320 . . . Post-treatment liquid, 410 . . . laminated substrate, 420 . . . substrate, 430 . . . element forming layer, 431 . . . nucleation layer, 432 . . . channel layer, 433 . . . Barrier layer, 434 . . . Cap layer, 450 . . . Etching target, 451 . . . Mask, 452 . . . region to be etched (Etched), 455 . . . top surface, 500 . . . group III nitride semiconductor device, 510 . . . semiconductor device, 520 . . . element separation groove, 521 . . . bottom surface (of element separation groove), 531 . . . source electrode, 532 . . . Gate electrode, 533 . . . Drain electrode, 540 . . . Protective film, 550 . . . Scribe line, 600 . . . Wafer, 610 . . . Chip, 700 . . . PEC etching device, 701 . . . PEC etching device, 710 . . . holding unit, 711 . . . holding table, 712 . . . rotating device, 720 . . . tank, 725 . . . recovery tank, 730 . . . supply unit, 731 . . . connection pipe, 732 . . . pump and switching valve, 733 . . . hose, 734 . . . moving mechanism, 735 . . . arm, 736 . . . pipe, 736a, 736b, 736c . . . (pipe) portion, 737 . . . discharge port, 740 . . . light irradiation device, 741 . . . attachment portion, 742 . . . Light, 743 . . . Light source, 745 . . . Light source, 746 . . . Light, 750 . . . Temperature control unit, 760 . . . Recovery unit, 761 . . . Recovery hose, 762 . . . Etching liquid monitor, 770 . . . Inner housing, 780 . . . Outer housing, 790 . . . control device, 800 . . . etching liquid, 810 . . . recovery etching liquid, 930 . . . supply unit, 931 . . . discharge port, 940 . . . light irradiation device, 941 . . . light source, 942 . . . light source, 943 . . . light, 944 . . . light

1. A structure manufacturing method, comprising:
preparing an etching target at least whose top surface comprises group III nitride crystal, and an alkaline or acidic etching liquid containing peroxodisulfate ion as an oxidizing agent that receives electrons;
irradiating the top surface of the etching target with light while rotating the etching target, with the top surface of the etching target immersed in the etching liquid heated to generate sulfate ion radicals.

2. The structure manufacturing method according to claim 1, wherein in the irradiation of the light, the top surface of the etching target is irradiated with the light while supplying the etching liquid onto the top surface of the etching target.

3. The structure manufacturing method according to claim 2, wherein in the irradiation of the light, an entire top surface of the etching target is immersed in the etching liquid, by rotating the etching target while supplying the etching liquid onto the top surface of the etching target without submerging the top surface of the etching target in the etching liquid.

4. The structure manufacturing method according to claim 1, wherein in the irradiation of the light, the light is obliquely emitted to the top surface of the etching target.

5. The structure manufacturing method according to claim 1, wherein in the irradiation of the light, the light is emitted so that a shadow of a member due to the light, the member constituting a structure manufacturing apparatus used in the structure manufacturing method, is not reflected on the top surface of the etching target.

6. The structure manufacturing method according to claim 1, wherein in the irradiation of the light, the light is emitted so that a shadow of a member due to the light, the member constituting a structure manufacturing apparatus used in the structure manufacturing method, is not reflected on a center of rotation on the top surface of the etching target, but is reflected on an outer peripheral side of the center.

7. The structure manufacturing method according to claim 1, wherein in the irradiation of the light, light containing at least a first light and a second light emitted from a direction different from the first light, is emitted as the light.

8. The structure manufacturing method according to claim 7, wherein in the irradiation of the light, the first light and the second light are emitted to improve uniformity of a distribution of irradiation intensity on the top surface of the etching target when both the first light and the second light are emitted, compared with a distribution of irradiation intensity on the top surface of the etching target when only one of the first light and the second light is emitted.

9. The structure manufacturing method according to claim 7, wherein in the irradiation of the light, the light is emitted so that a shadow of a member due to the first light, the member constituting a structure manufacturing apparatus used in the structure manufacturing method is reflected on the top surface of the etching target, and the second light is reflected on the shadow.

10. The structure manufacturing method according to claim 1, wherein in the irradiation of the light, by containing the etching target and the etching liquid in a container so that the top surface of the etching target is submerged in the etching liquid, an entire top surface of the etching target is immersed in the etching liquid, and by rotating the container, the etching liquid is rotated together with the etching target.

11. A structure manufacturing apparatus, comprising:
a holding unit that rotatably holds an etching target at least whose top surface comprises group III nitride crystal;
a supply unit that supplies an alkaline or acidic etching liquid containing peroxodisulfate ions as an oxidizing agent that receives electrons, onto the top surface of the etching target;
a heater that heats the etching liquid;
a light irradiation device that irradiates the top surface of the etching target with light;
a control device that controls the holding unit, the supply unit, the heater, and the light irradiation device to irradiate the top surface of the etching target with light while rotating the etching target, with the top surface of the etching target immersed in the etching liquid heated to generate sulfate ion radicals.

12. The structure manufacturing apparatus according to claim 11, wherein the control device controls the supply unit and the light irradiation device so that the top surface of the etching target is irradiated with the light while supplying the etching liquid onto the top surface of the etching target.

13. The structure manufacturing apparatus according to claim 12,
wherein the holding unit holds the etching target so that the top surface of the etching target is not submerged in the etching liquid, and
the control device controls the holding unit and the supply unit, so that an entire top surface of the etching target is immersed in the etching liquid, by rotating the etching target, while supplying the etching liquid onto the top surface of the etching target.

14. The structure manufacturing apparatus according to claim 11, wherein the light irradiation device obliquely irradiates the top surface of the etching target with the light.

15. The structure manufacturing apparatus according to claim 11, wherein the light irradiation device, the holding unit, and the member are arranged so that a shadow of a member due to the light, the member constituting the structure manufacturing apparatus, is not reflected on the top surface of the etching target.

16. The structure manufacturing apparatus according to claim 11, wherein the light irradiation device, the holding unit, and the member are arranged so that a shadow of a member due to the light, the member constituting the structure manufacturing apparatus, is not reflected on a center of rotation on the top surface of the etching target but is reflected on an outer peripheral side of the center.

17. The structure manufacturing apparatus according to claim 11, wherein the light irradiation device emits light including at least a first light and a second light emitted from a direction different from the first light, as the light.

18. The structure manufacturing apparatus according to claim 17, wherein the light irradiation device emits the first light and the second light, to improve uniformity of a distribution of irradiation intensity on the top surface of the etching target when both the first light and the second light are emitted, compared with a distribution of irradiation intensity on the top surface of the etching target when only one of the first light and the second light is emitted.

19. The structure manufacturing apparatus according to claim 17, wherein the light irradiation device emits the light, so that a shadow of the first light of a member constituting the structure manufacturing apparatus is reflected on the top surface of the etching target, and the second light hits on the shadow.

20. The structure manufacturing apparatus according to claim 11, wherein the holding unit includes a container configured such that an entire top surface of the etching target is immersed in the etching liquid by containing the etching target and the etching liquid so that the top surface of the etching target is submerged in the etching liquid, and by rotating the container, the etching liquid is rotated together with the etching target.
